(19) United States
(12) Patent Application Publication
(10) Pub. No.: US 2016/0326647 A1
(43) Pub. Date: Nov. 10, 2016

(54) ENTWINED MANIFOLDS FOR VAPOR DEPOSITION AND FLUID MIXING

(71) Applicant: Global OLED Technology LLC, Herndon, VA (US)

(72) Inventors: Rajeev ROHATGI, Reno, NV (US); Dhruv W. ROHATGI, Reno, NV (US)

(21) Appl. No.: 14/705,882

(22) Filed: May 6, 2015

Related U.S. Application Data
(63) Continuation of application No. 14/703,624, filed on May 4, 2015.

(51) Int. Cl. C23C 16/455; C23C 16/04; C23C 14/04

(52) U.S. Cl. CPC C23C 16/45574; C23C 14/04; C23C 16/04

(57) ABSTRACT

Entwined manifolds enable simultaneous but separate vapor deposition of different materials in interspersed patterns on a target substrate. A multi-manifold structure comprising a plurality of entwined manifolds is described. Methods of manufacture, methods of use, and systems for use are also described. The multi-manifold is suitable for PVD applications, including vapor deposition of emissive pixel materials for multi-color displays. Multi-manifolds are also suitable for CVD applications and for fluid mixing.

### CROSS-REFERENCE TO RELATED APPLICATIONS

This patent is a continuation of commonly assigned, co-pending U.S. Ser. No. 14/703,624, filed May 4, 2015, titled “Entwined manifolds for vapor deposition and fluid mixing” by Rohatgi et al, and which is incorporated by reference herein.

### FEDERALLY SPONSORED RESEARCH

Not applicable.

### FIELD OF THE INVENTION

The present invention relates to an apparatus comprising entwined manifolds suitable for simultaneous vapor deposition from multiple sources to patterned locations on a target object such as a display substrate. The inventive apparatus is also suitable for fluid mixing applications.

### BACKGROUND

Vapor deposition manufacturing techniques have been known for centuries, and are widely used. Two main variants are known: physical vapor deposition (PVD) and chemical vapor deposition (CVD). Physical vapor deposition involves condensation of material from a vapor onto a target surface. Chemical vapor deposition introduces a chemical reaction, so that the deposited material is formed in a chemical reaction at or near the target surface, but is not present in significant quantities in the vapor phase. CVD is a key technology used in the semiconductor industry, and is also widely used in microfabrication, nanotechnology, and specialized coatings. PVD is widely used in the semiconductor, automotive, and aerospace industries, and also for other specialized coatings. Many variants of PVD and CVD are known.

A survey of CVD may be found, for example, in (1) chapter 1 of Chemical Vapour Deposition: Precursors, Processes and Applications, eds. A. C. Jones and M. L. Hitchman, Royal Society of Chemistry, Cambridge, 2008, (2) H. Pederson and S. D. Elliott, Theoretical Chemistry Accounts, vol. 133, no. 5, article 1476, Springer-Verlag 2014, and their respective cited references. A survey of PVD may be found, for example in Physical Vapor Deposition of Thin Films, J. E. Mahan, Wiley-Interscience, New York, 2000. PVD of organic materials is described, for example by Barr in U.S. Pat. No. 2,447,789, and PVD for organic electroluminescent (EL) devices is described, for example, by Tanabe et al. in U.S. Pat. No. 6,296,894.

In many applications, an entire target surface is to be coated, and a single vapor source is applied uniformly to the entire surface. In other applications, a target surface is to be successively coated with multiple layers. In these applications, a sequence of vapor sources are successively applied to the target surface. In still other applications, a target surface is to be coated with a pattern. Masks, including aperture masks and photoresist masks, are widely used to limit deposition to the desired pattern. Successive layers may use different masks.

In a few applications, non-overlapping areas of a target surface are to be coated with different materials. One such common application is in the deposition of emissive materials in an organic EL display, which may have multi-color pixels, comprising for example, red, green, and blue sub-pixels, and different formulations for emissive materials for each color. Vapor deposition through aperture masks is commonly used in such applications, as described, for example, by Tang in U.S. Pat. No. 5,937,272. In an exemplary procedure, a first aperture mask is used to deposit red emissive material in the areas of the red sub-pixels, while leaving areas of green and blue sub-pixels uncoated. A second aperture mask is used to deposit blue emissive material in the areas of the blue sub-pixels, without affecting the red sub-pixels, and leaving the green sub-pixels uncoated. Finally, a third aperture mask is used to deposit green emissive material for the green sub-pixels. Depending on the pixel layout, a mask used for a first color can be translated by a step and re-used for at least a second color. In this way three manufacturing steps are required to deposit emissive materials for three colors, which is disadvantageous for the production cycle time (often referred to as TAKT time).

While this discussion describes three colors, it is known to use a different number of colors in a display, for example four, and even more. Some four-color combinations known in the art include red-green-blue-white (RGBW) and red-green-blue-yellow (RGBY). The considerations described here are similarly applicable to two colors, four colors, and five or more colors.

Prior attempts have been made to speed up the vapor deposition process. In U.S. Pat. No. 4,874,631, Jacobson et al. describe a system for simultaneous deposition of different coatings onto a thin web in a roll-to-roll manufacturing process. Different chambers are used for different coatings. With such a system it is difficult to maintain the precise registration required by fine-pitched pixels of today's commonplace display devices. In U.S. Pat. No. 6,338,874, Law et al. describe speeding up a multi-layer CVD process by performing all coatings within a single chamber. Law's system provides multiple CVD stations within a single chamber, thereby speeding up the turn-around from one coating to the next. However, as separate stations are used, only one CVD process can be performed at one time. Thus the bottleneck for display manufacture, namely requiring three process steps for three non-overlapping coatings, is not addressed by Law et al.

Another technology that has been developed is thermal transfer, in which a donor sheet is prepared offline, placed in proximity to the target surface. See e.g., U.S. Pat. No. 5,688,551 to Littman et al. Material is transferred from donor to target when the donor is heated. The donor may be heated selectively in a pattern. The pattern may be defined by (i) controlling in irradiating source, such as a scanning laser beam, (ii) by arranging absorber pads adjacent to the donor material, so that only material adjacent to an absorber pad is transferred to the target, or (iii) by preparing the donor sheet to have donor material only in defined areas. The pattern may also be defined (iv) using an optical mask, to limit areas of the donor sheet that receive irradiation, or (v) using an aperture mask, so material is only deposited through openings in the aperture mask.

Commonly, a donor sheet is prepared with a single material to be deposited. Accordingly, three steps with three donor sheets are required to deposit emissive materials for three colors. However, if the donor is prepared with material only in defined areas corresponding to sub-pixels, it is possible to prepare a single donor sheet with emissive material of all three colors, and thereby perform thermal transfer of all three colors in a single step. While this is advantageous for TAKT time, this technique suffers from two serious drawbacks. First, the donor sheet with multiple materials must be carefully prepared and is difficult to get properly registered. Secondly, such a donor sheet must be individually prepared for each target device, which becomes prohibitively expensive. Finally, the thermal transfer process itself has other difficulties, such as handling the donor sheets and providing a uniform, controlled irradiation source over a large area. As a result, the thermal transfer process is not widely used in the display industry, and vapor deposition remains the technology of choice.

As a result, there is still a need to provide improved methods and apparatus for vapor deposition, which can enable faster deposition of multi-color pixels with less process steps, lower production cycle time, and lower cost.

### BRIEF SUMMARY OF THE INVENTION

The present invention is directed to apparatus and methods for simultaneous vapor deposition from multiple sources onto distinct locations on a target surface.

In a first aspect, a multi-manifold apparatus is provided comprising a plurality of entwined disconnected manifolds. Each manifold has at least one input port and a plurality of output ports. In a PVD application, each input port may be connected to a PVD source. The manifold comprises one or more chambers and a plurality of pathways whereby vaporized material is delivered to the several output ports. In a display application, each output port may be aligned over a respective sub-pixel.

The manifolds are entwined, whereby each input port is simultaneously connected to all its corresponding output ports even as the output ports are arranged in interspersed patterns. For example, in a three-color display application, a red input port may be connected by a red manifold to output ports corresponding to all red sub-pixel locations, even while blue and green input ports are respectively connected to all output ports corresponding to blue and green sub-pixel locations. To achieve this, passageways for the red manifold must pass between multiple passageways of the blue and green manifolds.

The constituent manifolds of a multi-manifold are disconnected, which means that there are no internal pathways connecting one manifold to another.

The characterization of input ports and output ports is relative to a conventional PVD application with source material being delivered to a target surface. However, this designation is for convenience only: in some applications, one or more manifolds may be used in reverse. For example, in some CVD applications, pumping is provided to exhaust reaction by-products from the target surface area. In such embodiments, one or more manifolds may be used to deliver precursor material to the vicinity of the target surface, while one or more other manifolds may be used for exhaust. That is, the so-called input ports of an exhaust manifold would actually have outward flow of exhausted material into, for example, a pumping system.

In preferred embodiments, the multi-manifold is a metal structure, comprising metals such as stainless steel or titanium. In other embodiments, the multi-manifold is a polymer structure, or a ceramic structure. In still other embodiments, the multi-manifold is a composite, for example two or more sections of dissimilar materials joined together. In further preferred embodiments, the multi-manifold may have at least one section comprising layers of different materials, such as a polymer skeleton with a plated metal surface.

In a second aspect, the multi-manifold of the present invention is formed using an additive manufacturing (AM) process, sometimes colloquially referred to as 3-D printing. In some embodiments, the additive manufactured part itself comprises the multi-manifold. In other embodiments, an additive manufactured part is joined with other components to form a multi-manifold by any of a variety of technologies known in the art. In some embodiments, different additive manufacturing technologies may be used for two sections of a multi-manifold.

In a third aspect, manifolds in a multi-manifold may contain features to assist with flow-balancing between output ports. These features may include passageway extensions, shaped passages, and elements such as pins, baffles, and slant surfaces.

In a fourth aspect, manifolds in a multi-manifold may contain features to provide streamlined flow, inhibit formation of vortexes, and generally reduce the overall impedance between an input port and an output port.

In a fifth aspect, a multi-manifold is used in a process application during manufacture of a pixellated device. In some embodiments, the pixelated device is an organic electroluminescent display, such as an active matrix organic light-emitting diode (AMOLED) display.

Embodiments described here are not limited to displays, but are broadly applicable to a range of PVD and CVD applications. Embodiments are also applicable to other fields, such as to provide finely controlled mixing of two or more fluid streams.

In a sixth aspect, a multi-manifold is used in a CVD application to deliver precursors to a target surface. First and second precursors may be delivered using corresponding first and second manifolds of the multi-manifold. In some CVD applications, one or more of the manifolds of the multi-manifold may be used in reverse, as an exhaust to collect reaction byproducts.

In a seventh aspect a multi-manifold is used to mix two vapor streams. In engine technology, premixed fuel-air mixtures are well-known to improve combustion efficiency; separate fuel and air streams take time to mix and often have non-uniform concentrations at the time of combustion. A multi-manifold introduces two vapor streams in close proximity to each other, so that the distance over which mixing has to occur (and the associated time for mixing) is greatly reduced. Used this way, a multi-manifold has applications to a range of engine technologies, including vehicular and aerospace. The multi-manifold may also be used in general chemical reactor applications, for both liquid phase and gas phase reactors, where carefully controlled mixing is important.

In an eighth aspect, the multi-manifold can be used to mix two or more fluid streams, including all liquids, or some liquids and some vapors.

In a ninth aspect, a system for manufacturing a product uses a multi-manifold. In some embodiments, the system performs a PVD process step. In some preferred embodiments, the PVD process step comprises deposition of pixel materials onto a display substrate. In other embodiments, the system performs a CVD process step. In other embodiments, the system performs a fluid mixing step. In some embodiments, the system may comprise a chemical reactor, a bubble reactor, or a combustion chamber.

### Advantages of the Invention

Embodiments of this invention provide faster throughput and lower cost in the manufacture of multi-color displays such as organic electroluminescent displays. The multi-manifold allows all sub-pixels to be vapor deposited simultaneously, significantly reducing production cycle time and improving manufacturing throughput. The multi-manifold is reusable with very long lifetime, so that the initial cost to fabricate a multi-manifold is spread out over many manufacturing operations. Thereby the multi-manifold is very advantageous compared to alternatives presently used or contemplated in the display industry.

As long as the multi-manifold is maintained above vaporization temperature of vapor materials, there will be no significant deposition inside the manifolds. Further, as the multi-manifold is constructed of durable materials such as metal, polymer, and/or ceramic, it is straightforward to flush and clean the manifolds periodically, with gas, an inert liquid, or a solvent, with optional ultrasonication. Furthermore, metal and ceramic embodiments can be baked for optimum vacuum cleanliness.

Embodiments of this invention provide intimate, controlled, uniform mixing of two or more fluid streams, without allowing an opportunity for the fluids to react or mix earlier than desired. Thereby advantageous are obtained in CVD applications, engine technology, and other chemical reactors.

In some CVD embodiments, the use of one or more manifolds of the multi-manifold in reverse, for exhaust, allows efficient collection of reaction by-products, without contamination of neighboring reaction sites.

### BRIEF DESCRIPTION OF THE DRAWINGS

The following detailed description will be better understood when read in conjunction with the appended drawings, in which there is shown one or more of the multiple embodiments of the present invention. It should be understood, however, that the various embodiments of the present invention are not limited to the precise arrangements and instrumentalities shown in the drawings. Further, because of the widely disparate dimensions of the features shown, these drawings are not to scale.

FIG. 1 is a diagram of a display panel having three colors of sub-pixels arranged in stripes.

FIG. 2 is a diagram of a conventional aperture mask.

FIG. 3 is a diagram of a system in an operational state performing PVD through an aperture mask.

FIG. 4 is a diagram of a display panel having sub-pixels arranged in 2×2 blocks.

FIG. 5 is a diagram of a conventional aperture mask.

FIG. 6 shows a portion of an embodiment of a multi-manifold according to this invention, in isometric view.

FIG. 7 shows a portion of an embodiment of a multi-manifold in top view.

FIG. 8 shows a portion of an embodiment of a multi-manifold according to this invention, in isometric view.

FIG. 9 is a table of passages of a multi-manifold embodiment according to this invention.

FIG. 10 is a diagram showing a bottom view of a multi-manifold embodiment.

FIG. 11 is a diagram of a multi-manifold having unbalanced paths.

FIG. 12 is a diagram of a multi-manifold having balanced paths.

FIG. 13 is a diagram of a multi-manifold having a balanced four-way split.

FIG. 14 is a diagram of an electrical circuit analog for flow in passages.

FIG. 15 is a diagram of a multi-manifold having flow-balancing features.

FIG. 16 is a diagram of a multi-manifold having streamlining features.

FIG. 17 is a diagram of a multi-manifold having a long, substantially vertical first-level passageway.

FIG. 18A is a table of passages of a multi-manifold embodiment according to this invention.

FIG. 18B is a graph showing passage width for layers of the multi-manifold embodiment of FIG. 18A.

FIG. 19A is a table of passages of a multi-manifold embodiment according to this invention.

FIG. 19B is a graph showing passage width for layers of the multi-manifold embodiment of FIG. 19A.

FIG. 20 is a diagram showing a bottom view of an attempted design of a multi-manifold embodiment.

FIG. 21 is a diagram showing a bottom view of a multi-manifold embodiment.

FIG. 22 is a cross-sectional view AA′ of the embodiment of FIG. 21, during operation.

FIG. 23 is a diagram showing an embodiment of a multi-manifold having interlocking first-level passages.

FIG. 24 is a diagram of a display panel having sub-pixels arranged in 2×2 blocks.

FIG. 25 is a diagram of a two-way split first-level structure for a multi-manifold embodiment.

FIGS. 26-27 are diagrams of multi-manifold embodiments incorporating the structure of FIG. 25.

FIGS. 28-31 are flowcharts for manufacturing methods of this invention.

FIG. 32 is a diagram of an embodiment of this invention for PVD.

FIG. 33 is a flowchart for a PVD method of this invention.

FIG. 34 is a diagram of an embodiment of this invention for CVD.

FIG. 35 is a flowchart for a CVD method of this invention.

FIG. 36 is a diagram of a fluid-mixing embodiment of this invention.

FIG. 37 is a flowchart for a fluid-mixing method of this invention.

FIG. 38 is a diagram of a fluid-mixing embodiment of this invention.

### DETAILED DESCRIPTION OF THE INVENTION

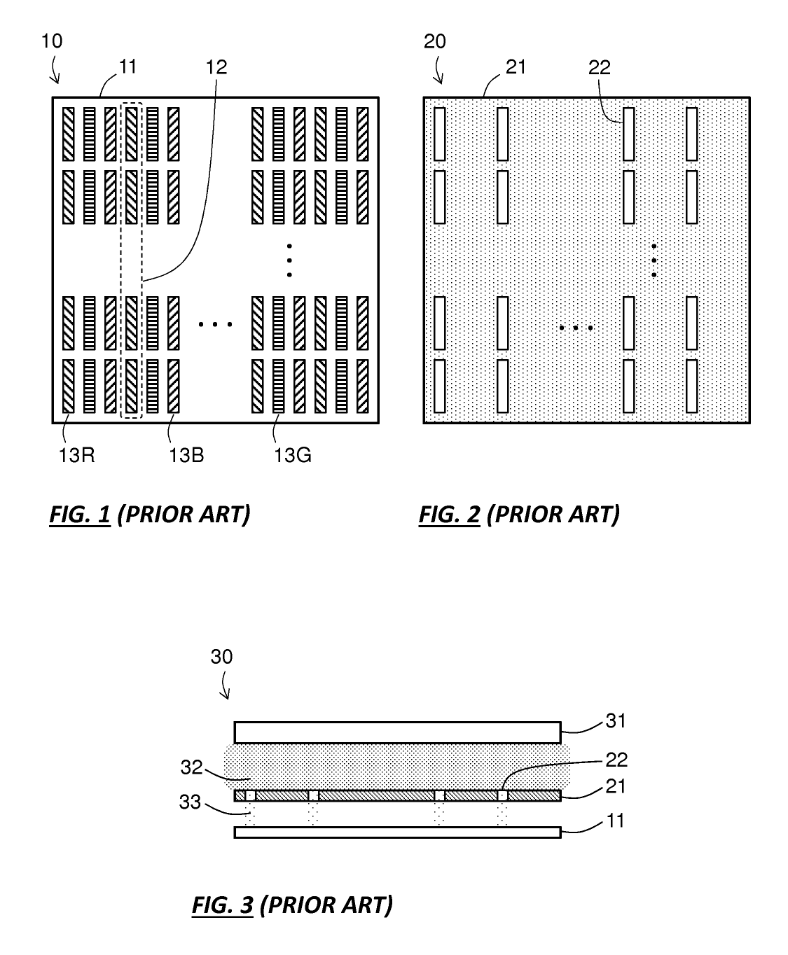

FIG. 1 is a diagram showing a display 10 having a striped pixel layout. Red sub-pixels 13R, green sub-pixels 13G, and blue sub-pixels 13B are formed on panel 11. Sub-pixels of each color are organized in stripes. Dashed line 12 shows one such stripe comprising only red sub-pixels.

In this document, the term “sub-pixel” will be used to denote a distinct light-emitting element in any of a display product or a lighting product. Sub-pixels may have different colors and may be grouped together to form pixels. A pixel has at least one of each color sub-pixel, and cannot be sub-divided into smaller pixels. Pixels are usually arranged in a regular two-dimensional array, which is often organized as rows and columns, as will be familiar to one of ordinary skill in the art. Rows and columns are interchangeable.

It is also useful to define the concept of neighboring elements in such an array. Consider first and second elements of such an array, which have respective first and second centroids. The first and second elements are neighbors if the number of distinct points on the top surface of the substrate that are (a) equidistant from first and second centroid, and (b) farther from the centroids of all other elements of the array, is greater than or equal to two. According to this definition of “neighbor” two adjacent squares on a chessboard are neighbors (all except corner points along their common boundary satisfy both conditions (a) and (b)), two diagonally touching squares on the chessboard are not neighbors (the corner where the squares touch is equidistant from four squares of the chessboard, hence this point does not satisfy condition (b), and no other point meets both conditions (a) and (b) either), and two squares remote from each other on the chessboard are not neighbors (all points satisfying condition (a) are closer to the centroid of some third square than to the first and second centroids).

FIG. 2 shows a conventional aperture mask 20 that can be used for vapor deposition of red sub-pixels 13R. Aperture mask 20 comprises a plurality of apertures 22 formed in a sheet 21. A similar aperture mask (or, even the same aperture mask shifted to the right by one or two times the pixel pitch) can be used to deposit green and red sub-pixels 13G, 13B in successive PVD process steps.

FIG. 3 shows an operational system 30 performing vapor deposition of red sub-pixels onto panel 11 through aperture mask 20. PVD source 31 provides vapor of red sub-pixel material 32 in the space above the aperture mask. Vapor 33 passes through the apertures 22 and is deposited in corresponding locations on panel 11 to form a patterned layer of red sub-pixels 13R. On a subsequent process step (not shown), a different PVD source is used to deposit material through differently positioned apertures onto panel 11, thereby to form green sub-pixels 13G and blue sub-pixels 13B respectively. A PVD source may comprise a stock of vaporizable material and vaporization apparatus such as a heated crucible, an auger feed, and/or a flash vaporization heating element.

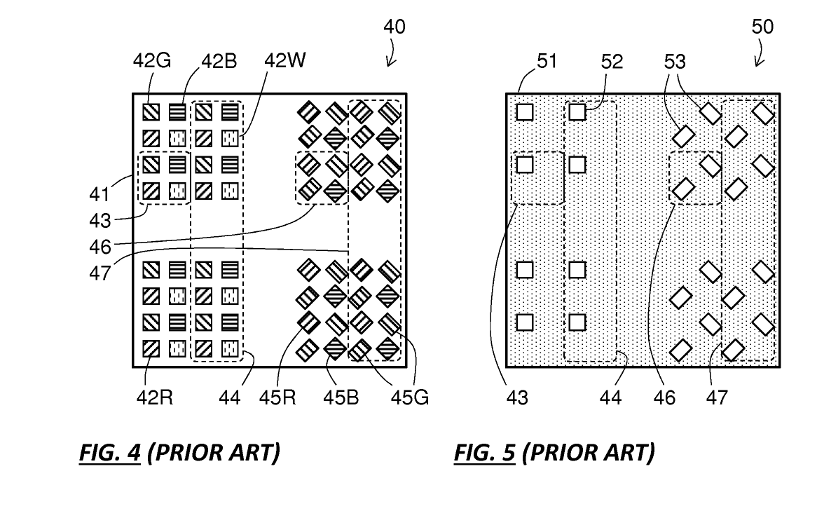

FIG. 4 is a diagram of an exemplary display 40 having a block pixel layout. Two different pixel patterns are shown for illustration purposes only: while there is no prohibition against mixing patterns within one display, it is customary in the art to use just one pattern in any particular display. On the left side of panel 41 is a pixel 43 organized as a 2×2 block of sub-pixels. In this block are one each of a red sub-pixel 42R, a green sub-pixel 42G, a blue sub-pixel 42B, and a white sub-pixel 42W. Pixels 43 repeat in both row and column direction. Dashed line 44 shows a column-wise stripe of pixels. On the right of the display is shown pixel 46 having a different 2×2 block layout. Unlike block 43, the sub-pixels of pixel 46 are obliquely oriented. Further, pixel 46 has four sub-pixels of only three colors. This so-called RGBG layout has one red sub-pixel 45R, two green sub-pixels 45G, and one blue sub-pixel 45B in each pixel 46.

In the block patterns of FIG. 4, no sub-pixel has a neighboring sub-pixel of the same color. Consistent with the earlier definition of neighbor, a sub-pixel's neighbors are the adjacent sub-pixels along a row or column of sub-pixels in FIG. 4; pixels along a diagonal are not neighbors.

FIG. 5 shows a conventional aperture mask 50 that can be used for vapor deposition of sub-pixels 42G and 45G. Apertures 52 in sheet 51 provide a pattern corresponding to sub-pixels 42G, while apertures 53 provide a pattern corresponding to sub-pixels 45G. Use of aperture mask 50 to deposit patterned sub-pixels of display 40 is similar to that illustrated in FIG. 3. Pixel and stripe outlines 43, 44, 46, 47 are reproduced in FIG. 5 for clarity.

### First Embodiment Class

### Multi-Manifold with Striped Output Ports

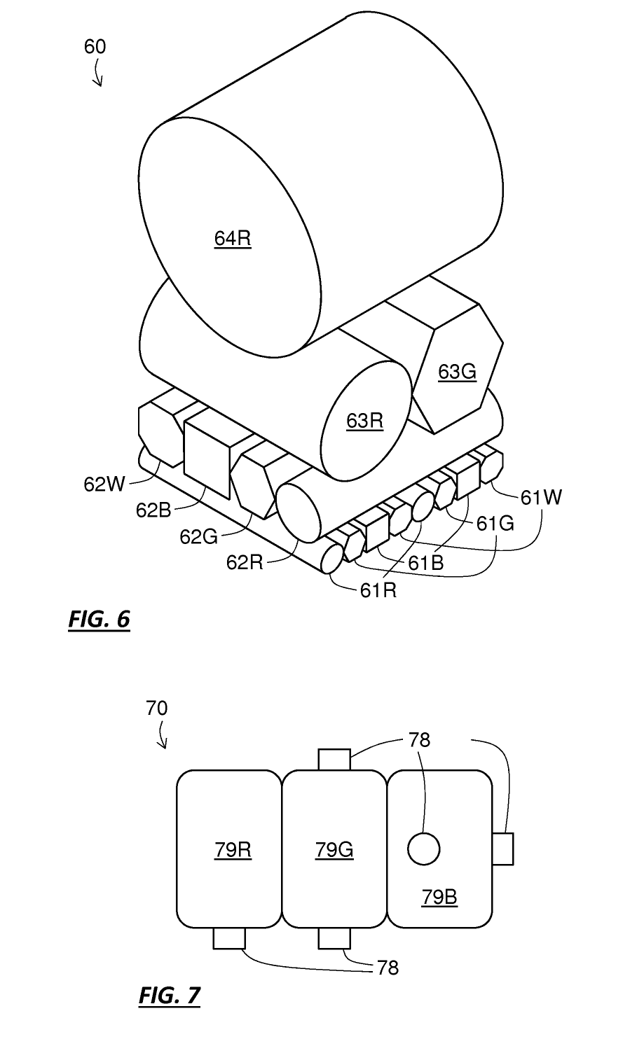

FIG. 6 shows a portion of an embodiment of a multi-manifold 60 that allows interspersed patterns of several materials to be deposited simultaneously on a target substrate. This embodiment will be described in terms of vapor flow in a display PVD application, however it will be understood that the invention is not so limited, and a multi-manifold can be used for transport and distribution of substantially any fluid materials in substantially any suitable application. Fluids may include, for example, liquids, gases, suspensions, colloids, smoke, and mixed-phase fluids such as aerosol streams or liquids with entrained bubbles.

Multi-manifolds are described herein as having top and bottom. This is merely a convenience, relative to an operational configuration in which a multi-manifold is operated above a target substrate, with output ports on the bottom of the multi-manifold facing the target substrate. Then, the top surface of the substrate faces the output ports and is termed the facing surface of the target substrate. A PVD source (or, other fluid source, or a pump) is connected to an input port at the top part of the multi-manifold. The manifold provides connectivity between output ports and input port(s). One of ordinary skill in the art will understand that the usage of top and bottom, and related terms, is a matter of convention and used consistently for clarity, whereas in actual practice PVD may be performed upside-down, sideways, or in any other orientation besides downward onto a substrate.

Multi-manifold 60 comprises passageways arranged in layers. Generally, as there are many interspersed output ports, output ports are connected to fine-pitch passageways. At the bottom of the multi-manifold, these passageways are called first-level (or, layer 1) passageways. Generally, each manifold may have only a few input ports, which are consequently larger in size than the first-level passageways. A large passageway may be described as a chamber or a plenum. Indeed the terms “chamber”, “plenum”, “passage”, and “passageway” all refer to confined spaces in which a fluid or vapor can be confined and transported; these terms are used interchangeably throughout this disclosure. Likewise, passageways can be thought of as existing on respective levels of the multi-level structure of a multi-manifold. The passageways on a particular level comprise a layer. Thus, in this disclosure, the terms “level” and “layer” are used interchangeably.

At the lowest level of the multi-manifold, 61R, 61G, 61B, and 61W are first-level passageways for emissive layer materials for red, green, blue, and white sub-pixels respectively, organized as a repeating group of parallel passageways. Each first-level passageway comprises a series of output ports (or, one long output port) on the bottom (not shown). In operation, one passageway 61R can be understood to be aligned with and directly above one stripe of a desired pixel pattern similar to 12 shown in FIG. 1. Thereby emissive layer material exiting the multi-manifold 60 is deposited in the desired pattern. That is, the output ports perform a similar function as the apertures 21 shown in FIG. 3. Moreover, the output ports for all the several colors together simultaneously provide apertures for each of the several colors, enabling simultaneous deposition of materials for the several colors and improving process efficiency. In many embodiments, all output ports of a multi-manifold lie in a common plane. The patterns of the output ports of the several manifolds are interspersed in a pattern in this plane that matches a desired pattern on a target, for example, a pixel pattern on a display. As the desired pixel pattern on a target substrate comprises stripes of sub-pixels, so also the output ports of associated manifolds may form stripes on the bottom of the multi-manifold. Each output port stripe is respectively connected to one or more collinear layer 1 passageways.

Above the first layer, passageways are connected to successively higher layers of passageways, with no connection between passageways associated with different sub-pixel colors. In common embodiments, layer 2 comprises passageways that are orthogonal to the passageways of layer 1.

For the purposes of illustration, the passageways for different colors have been shown with different cross-sectional shapes. It will be understood by one of ordinary skill in the art that, while there is no prohibition against using a mix of different shapes (including other shapes not shown), most multi-manifold embodiments will use the same cross-sectional shape for all passageways in a given layer. Further, the passageways have been drawn with a 1:1 cross-sectional aspect ratio, that is height=width. This is by no means necessary. At lower layers, where passageways are very narrow, it may be desirable to have height greater than width, while at higher layers, where passageways are very broad, it may be desirable to have height less than width.

Observing the passageways shown with cylindrical cross-section (associated with red sub-pixels), it can be seen that each passageway 61R at the first level is in contact with passageway 62R at the second level, which is in contact with passageway 63R at the third level, which in turn is in contact with passageway 64R at the fourth level. Each pair of adjoining passageways is connected by an aperture, so that vapor material from passageway 64R can flow into passageway 63R, and thence to passageways 62R and 61R.

FIG. 6 shows only eight first-level passageways. However in display applications, the number of display pattern stripes may be in the hundreds, thousands, or more. Accordingly, the fourth level shown may not be the top layer of the multi-manifold; there may be additional layers as passageways are joined together in smaller numbers of larger passageways until a single chamber for each color is reached. This single chamber, at the highest level of the manifold, has one or more input ports for attachment of a PVD source.

FIG. 7 shows a top view of a portion of a multi-manifold 70. The top layer comprises three chambers 79R, 79G, 79B for each of three constituent manifolds of multi-manifold 70. Chamber 79R has a single side-mounted input port 78. Chamber 79G has two side-mounted input ports 78. Chamber 79B has two input ports 78, one side-mounted and one top-mounted.

Considering just the passageways associated with red sub-pixels, there is an input port and a single chamber at the highest level, and a plurality of output ports at the lowest level. The input port is connected to all output ports through the network of passageways at the several levels. Even where there are multiple input ports, there will in general be considerably more output ports than input ports, and all input ports are connected to all output ports through the network of passageways. All passageways are defined by walls. Accordingly, the input port(s), the output ports, the passageways, and defining walls comprise a manifold associated with the red sub-pixels. Similarly, a different set of input port(s), output ports, passageways, and walls comprise a manifold associated with the green sub-pixels. Similarly, third and fourth sets of ports, passageways, and walls comprise respective manifolds associated with the blue sub-pixels and the white sub-pixels. These manifolds share no ports and share no passageways. There are no connecting paths internal to the multi-manifold by which fluid can mix between the manifold associated with red sub-pixels and the manifold associated with green sub-pixels, or between any pair of the manifolds. The manifolds are entwined, as necessary for each manifold to be able to simultaneously provide connectivity to all of its respective output ports.

Walls are shared only to the extent that a wall may separate a passageway belonging to one manifold from a passageway belonging to a different manifold. Such walls can be considered conceptually to be a laminate of two walls, one facing and confining a passageway of a first manifold, the other facing and confining a passageway of a second manifold. It should be noted that the two walls may not be distinguishable upon physical examination; the conceptual separation of one wall into two is merely a convenience that allows the walls also to be regarded as not being shared between manifolds, so that the manifolds associated with different color sub-pixels can be regarded as wholly distinct.

Additionally, a multi-manifold may comprise some void space, defined as a space that is within the overall extent of the multi-manifold, is not filled with solid, and is not part of any passageway of any constituent manifold. For example, in FIG. 6, a void space may exist between passages 63R, 63G, and 64R. Of course, a manifold wall may separate a passageway of the manifold from void space. In some embodiments, void space may be partially or wholly filled during the manufacturing process.

As described for the passageways associated with red sub-pixels, so also for the other colors. The two passageways 61G on the first level are connected to passageway 62G on the second level, which in turn is connected to passageway 63G on the third level, and so on. Due to the finite extent of the portion of multi-manifold 60 illustrated in FIG. 6, passageways associated with green sub-pixels above the third level are not shown. The two passageways 61B on the first level are connected to passageway 62B on the second level, and so on to higher levels. The two passageways 61W on the first level are connected to passageway 62W on the second level, and so on to higher levels.

Accordingly, multi-manifold 60 comprises four manifolds—one each for deposition of red, green, blue and white sub-pixel material. These four manifolds are entwined, and are disconnected from each other, which means that there are no internal paths allowing fluid from one of the manifolds to mix with fluid of another of the manifolds. However, there is no prohibition between two ports of different manifolds being connected to one another externally, either intentionally or inadvertently. In some applications it may be desirable to couple input ports of two manifolds to a same source. For example, a multi-manifold for a four-color display layout may comprise four entwined manifolds, but if the application is a display with RGBG-patterned pixels, i.e. with two green sub-pixels in each pixel, then two of the four manifolds will be used to deposit green sub-pixel material and may be connected to a same common PVD source.

Likewise, there is no prohibition between material from the output ports commingling, which may occur by design or inadvertently. For example, in a display application it may be desirable not to have the deposition of red material end abruptly at the end of the emissive area of a red sub-pixel. Rather it may be desirable to have red material taper off smoothly between the red emissive area and an adjacent emissive area of a blue sub-pixel, and likewise have the blue sub-pixel material taper off gradually from the edge of the emissive area of the blue sub-pixel towards the red sub-pixel. Thereby, in between red and blue sub-pixels, both red and blue sub-pixel materials are commingled, and a smooth surface contour is maintained. In other applications, such commingling is undesirable. Banks may be formed on the target surface, so that each sub-pixel is confined to a recessed area surrounded by banks. If the output ports are brought into close proximity to the raised bank surfaces, even touching, then commingling can be substantially prevented.

As a general rule, each manifold of a multi-manifold has less input ports than output ports. As a general rule, each manifold of a multi-manifold has larger openings for each input port than for each output port.

FIG. 6 shows a portion of multi-manifold 60, and provides little indication of the length of each passageway. In some embodiments, all passageways extend the full extent of a target display, whether in the row direction or in the column direction. In other embodiments, the passageways are segmented. The term target display is in context of a PVD process, and may be substantially synonymous with the display of a finished product such as a television, or may be a motherglass which is considerably larger than a finished display product.

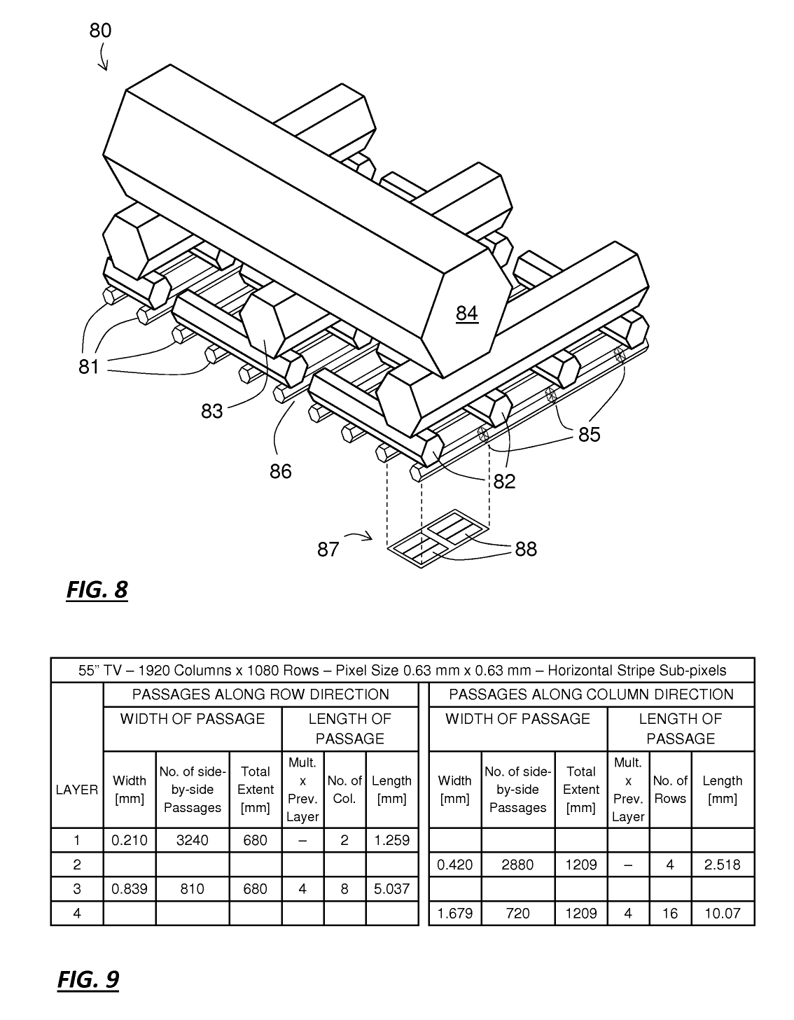

FIG. 8 shows a portion of a multi-manifold 80 having segmented passages. In order to clearly illustrate the architecture, only one manifold is shown. Whereas multi-manifold 60 comprised four manifolds, multi-manifold 80 is drawn with passageway dimensions and spacing chosen suitably for a three-color display.

First-level passageways 81 provide output ports (not visible) for discharge of vapor material onto a target. For reference, 87 shows two pixels of a display pattern shown aligned in an operational configuration beneath multi-manifold 80. (These pixels are not part of multi-manifold 80.) These pixels are laid out in a stripe configuration; sub-pixels 88 are directly beneath one 81 passageway. Three septa 85 are shown by dotted patterns; these septa serve to define the extent of each 81 passageway as equal to the length of two pixels 88. That is, a pixel stripe extending across the extent of the display for a length of 2M pixels is fed by M collinear first-level passageways. Each of these collinear first-level passageways is connected to a different second-level passageway 82. As shown, each 81 passageway serves two sub-pixels, each 82 passageway serves four 81 passageways, each 83 passageway serves four 82 passageways, and the one 84 passageway shown serves all three visible 83 passageways.

FIG. 9 presents a table whereby the design of multi-manifold 80 can be better understood. In the top row, the application is described, which is a 55″ full high-definition television having pixels organized as 1920 columns by 1080 rows. Each pixel is nominally a square 0.63 mm on a side. The sub-pixels are organized as horizontal stripes (that is, the stripes are parallel to the row direction). The table contains one row for each layer of multi-manifold 80; consistent with FIG. 8, only the first four levels are shown in the table (higher layers are discussed further below). For clarity, layers 1 and 3 with row-wise passageways are shown separately from layers 2 and 4 having column-wise passageways.

In layer 1, each passage is in the row direction and has a width of 0.210 mm, which is just the sub-pixel width 0.630 mm divided by 3. (Gaps between sub-pixels and between pixels are ignored in the present discussion for simplicity. The sub-pixel width is taken to be the sub-pixel pitch in the width direction.) There are 3240 passages side-by-side (3 passages for each row of pixels), and the total extent 680 mm matches the extent of the television set. Each passage extends the length of two columns (that is, between two adjacent septa 85) and has a length equal to the row-wise length of two pixels, 2×0.63 mm=1.259 mm (to within a small inconsequential rounding discrepancy).

In layer 2, the passages are in the column direction. Each first-level passage has two mates serving the same pixels for the other two colors. Accordingly, the length 1.259 mm of each first-level passage must be able to accommodate three second-level passages, and the width of each second-level passage is 1.259 mm/3=0.420 mm. The number of side-by-side second-level passages is 2880, which is three passages for every two pixels in the row direction: (1920/2)×3=2880. The total extent of these passages is 1209 mm, which matches the extent of the television set. Each passage extends the length of four rows of pixels, which is 4×0.63 mm=2.518 mm (again, within rounding).

Moving to layer 3, once again the passages are in the row direction. The length of the layer 2 passages must be served by three layer 3 passages, so the width of each passage is 2.518 mm/3=0.839 mm. The number of side-by-side passages is 810; that is, three for every four rows of pixels: (1080/4)×3=810. As a check, the total extent 680 mm matches the extent of the television set. The previous row-wise layer was layer 1, where each passage had a length covering 2 columns. In layer 3, the length is multiplied by four compared to layer 1 (4×1.259 mm=5.037 mm), covering eight columns.

The calculation for layer 4 is similar. Passage width is based off the length of layer 3 passages, and passage length is scaled up from the length of layer 2 passages.

At layer 1 in the passage width direction, 3240 passages are organized side-by-side. In the length direction, each passage has a length of 2 columns, so there are 1920/2=960 collinear first-level passages for each stripe of sub-pixels. Altogether the number of layer 1 passages is 3240×960=3,110,400. Similarly at layer 2, the total number of passages is 2880×(1080/4)=777,600. The total number of layer 2 passages is less than the total number of layer 1 passages. In common designs, the height of passages is comparable and often equal to the width of those passages, particularly at the lower levels. So, as the width of passages increases with increasing layer number, the cross-sectional area of the passages also increases. Sometimes in a design, two successive layers have the same passage width. In the design of FIG. 9, passages in layer 2 have twice the width of passages in layer 1. As depicted in FIG. 8, layer 2 passages are also twice the height of layer 1 passages, although this is not a necessary feature. Accordingly, in embodiments like that shown in FIGS. 8 and 9, the cross-sectional area of a layer 2 passage is greater than the cross-sectional area of a layer 1 passage.

Similarly, the design of FIGS. 8 and 9 has layer 3 passages that are fewer in number and have greater cross-sectional area than the layer 2 passages.

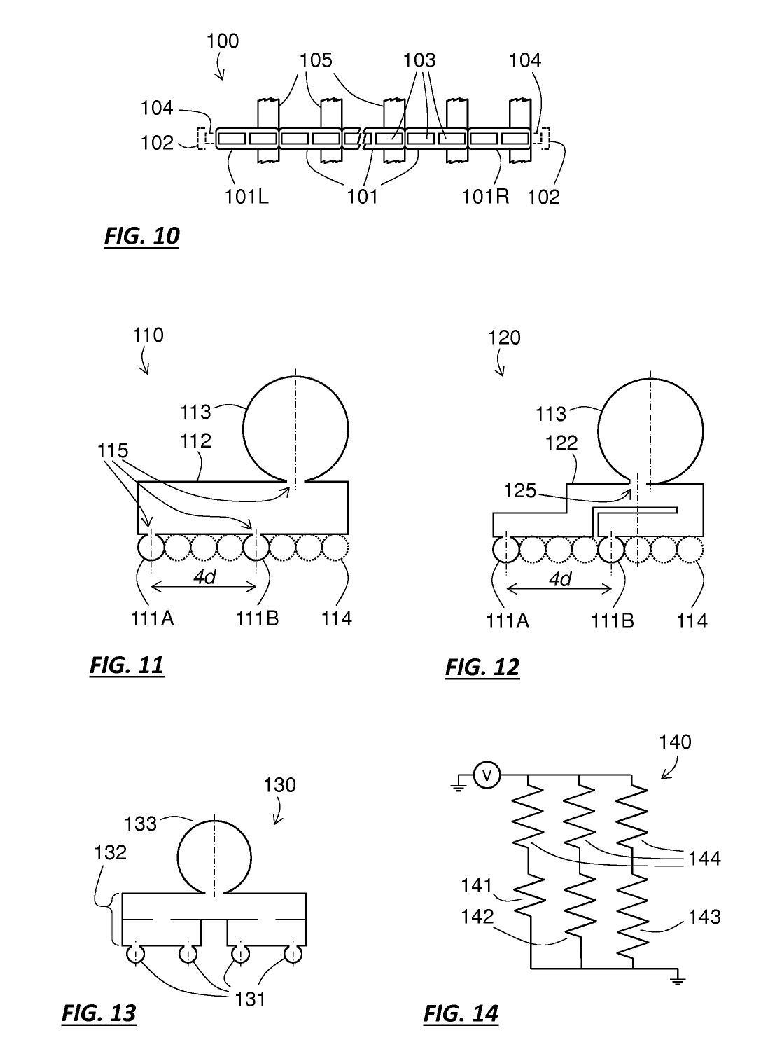

FIG. 10 shows a bottom view of a portion of an embodiment of a multi-manifold. For clarity of illustration only elements of one manifold 100 are shown. A series of collinear first-level passages 101 is shown, including 101L at the left-most edge of the multi-manifold and 101R at the right-most edge of the multi-manifold. These passages form a stripe 102, as indicated by dashed markings. A series of output ports 103 is also shown, forming a stripe 104 indicated by dashed markings. Stripe 104 comprises only output ports of the instant manifold. Output ports of other manifolds are arranged in respective stripes parallel to 104. Every output port 103 is directly connected to and/or part of exactly one first-level passage 101. Stripes 102 and 104 are parallel. In preferred embodiments, each first-level passage comprises an equal number of output ports 103. In the embodiment shown, there are two output ports 103 on each first-level passage. In some embodiments, one or both of the end first-level passages 101L and 101R may have a different number of output ports, while all other passages in stripe 102 have an equal number of output ports 103. This may be the case if the number of output ports in stripe 104 is not an integer multiple of the number of collinear first-level passages in stripe 102. In other embodiments, the various manifolds may be designed with staggered patterns, which is one way to facilitate fitting together various manifolds of a multi-manifold in three dimensions, and this too may require managing uneven grouping of output ports at the end of a stripe.

FIG. 10 also shows a series of second-level passages 105, each of which is connected to a different first-level passage 101. Likewise, each first-level passage in stripe 102 is connected to a different second-level passage 105. In some embodiments, the second-level passages are perpendicular to the first-level passages. Turning back to FIG. 8, each second-level passage 82 is connected to four first-level passages 81 associated with different sub-pixel stripes. In preferred embodiments, all or substantially all second-level passages are connected to an equal number N₂ of first-level passages, with possible exceptions being at the edges of the multi-manifold for reasons similar to those described above. N₂ may be preferably two, or four as shown in FIG. 8, or it may be a different number according to a particular design.

### Topology

Turning back to FIG. 8, septa 85 are shown separating first-level passageways in between successive second-level passageways 82. Gaps 86 are shown separating two successive collinear second-level passageways 82 in between successive third-level passageways 84. That is, each first-level passageway is served by a single second-level passageway, and each second-level passageway is served by a single third-level passageway. Continuing in similar fashion up through the layers of manifold 80, all passageways at level K are served by exactly one passageway at level K−1 until a single chamber at the top-most level is reached. Accordingly, there is a unique path from the top-most chamber to any first-level passageway through the manifold 80. Thus, manifold 80 has no closed loops, and has the topology of a tree. Conceptually, manifold 80 can be disentangled from the rest of an encompassing multi-manifold.

The choice of whether to use septa such as 85 or gaps such as 86 is a matter of design. Generally, septa may be preferred at lower levels because of the smaller dimensions of all features and (for layer 1) very small gaps that may be present between adjacent output ports. Gaps may be preferred at higher levels, in order to minimize dead space of stubs at the ends of a passageway that provide no connection to either an upper or lower layer.

In other embodiments, at least one layer has no septa or gaps, and at least one passageway at that layer is connected to a plurality of passageways at the next higher layer. Presuming that such an embodiment converges to a single chamber at the highest layer, such a manifold has at least one closed loop. If two or more manifolds of a multi-manifold have closed loops, then the manifolds may be interpenetrating, which means that the manifolds have intersecting closed loops such that it is not conceptually possible to separate the manifolds without breaking at least one closed loop.

In the extreme case, and opposite to the tree topology described above, all passageways extend to the full extent of the multi-manifold, all passageways at intermediate layers K are connected to all passageways in layer K−1 and all passageways in layer K+1. A manifold such as this may have a very large number of paths from a single chamber at the highest level to any output port, and may be described as maximally connected.

### Flow Balancing

It is generally desirable to have uniform deposition of vaporized materials over pattern elements across the extent of a display. To achieve this, it is desirable to design each manifold of a multi-manifold to have balanced flow to all its output ports. It is not necessary that flow of two different manifolds be balanced, however as different manifolds within a multi-manifold generally have very similar design, balanced flow between manifolds is often straightforward to achieve. However it should be noted that even identical manifolds may exhibit differences in flow owing to the different characteristics of different vaporized materials and different characteristics of the PVD sources.

Returning to flow balancing within a single manifold, this is equivalent to having equal impedance from the input port to any output port. Since a PVD vapor is a compressible gas, and a heated multi-manifold constrains the PVD vapor to an isothermal condition, we can examine the flow using a form of the general flow equation for isothermal compressible gas flow in a pipe:

Q=C₁·(ΔP^{0.5})·(D^{2.5})/(L·f)^{0.5} (1)

where Q is the flow rate, C₁ is a constant of proportionality, ΔP is the pressure drop, L is the pipe length, and f is a friction factor. See e.g. Gas Pipeline Hydraulics, Menon et al., Trafford, 2013, pp. 44-45. Here, an assumption has been made that the pressure drop is relatively small compared to the average pressure. Generally f increases for smaller D, so f can be removed in favor of a higher exponent for D. At low flow rates, f∝1/D, in which case elimination off changes the D exponent to 3. At higher flow rates, different authors use different approximations, with the D exponent typically between 2.6 and 2.7. For the qualitative purpose of the present discussion, an approximate exponent of 2.8 will suffice. Hence

Q=C₂·(ΔP^{0.5})·(D^{2.8})/(L^{0.5}) (2)

where C₂ is another constant of proportionality.

At any particular layer, there will be N passages through which vapor flows in parallel; NQ is the total flow through this layer and is the same for all layers, and N·D·L is approximately the total area of the display, which is also constant. Further, we introduce Z=L/D for the aspect ratio of a passage. Rearranging terms, squaring, and absorbing total flow and total area into another constant of proportionality C₃, the following formula is obtained:

ΔP=C₃·Z³·D^{-0.6} (3)

Using this formula, it is possible to compare the pressure drop across different layers; higher pressure drop is synonymous with greater impedance to flow. The effect of diameter D is modest: in a TV sized display, D may vary by ˜100 from the lowest layer to the highest layer, with consequently 15× higher pressure drop at the lowest layer. On the other hand, a layer having 5× higher aspect ratio (typically, an upper layer) may have 125× higher pressure drop! So, a short path segment through a passage at this layer (to the next lower layer) has significantly lower impedance than a long path segment at this layer. Consequently, the flow on the short path may be appreciably greater than on the long path, to the detriment of uniform vapor deposition.

Eqn. (1) can be seen to imply that for a given flow rate, pressure drop varies as D⁻⁵. Accordingly, it might be expected that the dominant contribution to flow impedance should come from the first level of an inventive manifold of the type described above, and the result of Eqn. (3) may be surprising. However, the inventive manifold is different from a simple pipe section. As D decreases going toward lower levels, the number of parallel passageways correspondingly increases. Furthermore, the passageway lengths also decrease. Accordingly, the contribution of a layer to flow impedance increases only modestly as diameter decreases, and a small change in aspect ratio may counteract this effect completely.

Therefore, it is important that passages be designed to balance flow for different paths.

The easiest way to balance flow is to design each layer to be a symmetric two-way split. This means that a passage at layer K (for some K>1) connects to exactly two passages at layer K−1. With a two-way split, if the paths are equal, then their impedance contributions at layer K are also equal. If the attached lower layer networks of passages are identical, then the flow at layer K will be split equally between the two attached layer K−1 passages.

However, even a two-way split may require careful design. FIG. 11 shows a cross-section of a portion of a manifold 110 within a multi-manifold. 111A and 111B are two passageways of a layer K having extending lengthwise perpendicular to the plane of the Figure. These passageways connect to a transverse passage 112 at layer K+1 via apertures 115. Passage 112 in turn connects to passage 113 at layer K+2 which is parallel to passages 111A, 111B, via another aperture 115. Also shown as dotted lines at layer K are positions of passages 114 belonging to other manifolds of the instant multi-manifold. The diameter of each layer K passageway is d; the center-to-center spacing between passages 111A and 111B is 4d. As shown, 111A and 111B are positioned asymmetrically with respect to passage 112. Passage 113 is also positioned asymmetrically with respect to passageway 112. Accordingly, the paths from 111A and 111B through passage 112 to passage 113 are unbalanced: the vertical displacements are the same, but the horizontal displacements are 5.5d and 1.5d respectively.

FIG. 12 shows a cross-section of a corresponding section of a modified manifold that has balanced paths. The positions and extents of passages 111A, 111B, 122, and 113 are unchanged from those shown in FIG. 11. Passage 122 has been partitioned to increase the path length from passage 111B to passage 113, and aperture 125 has been shifted by d/2 to the left. As a result, the paths from 111A and 111B to 113 each have horizontal displacement of 5d, and the same vertical displacement. Thus, the paths are balanced.

A two-way flow-balanced split can be extended to a four-way split. FIG. 13 shows a portion of a multi-manifold 130 in which layer K passage 132 connects four layer K−1 passages 131 to a K+1 passage 133. The passages 131 are first connected together in pairs, and the connected pairs are also connected together. As the entire structure is symmetric, flows from passage 133 to all four passages 131 are balanced.

However, it may not always be possible to use only two-way splits. For example, the prime factorization of 1080=2³·3³·5. Accordingly, only three layers can be arranged as a two-way split. Beyond that, one possibility is for some layers must be split according to multiples of 3 or 5. Another possibility is to have unbalanced passageways at some level: for example 3.5=15=4+4+4+3, so that a 15-way split can be achieved by combining 3×4-way splits (each of which can be a cascade of two 2-way splits) and 1×3-way split. Another difficulty may arise even when 2-way splits are possible: for example 2048=2¹¹. Implemented as two-way splits, this requires 11 layers just for grouping of passageways in one dimension, with a similar number of layers likely required for grouping passageways in the orthogonal direction. A multi-manifold design with 20 or more levels may be considered unduly complex, and it may be desired to have a lower layer count for reasons of cost and size.

Luckily, there are other strategies for balancing flow. One such strategy is to introduce additional impedance into all paths, so that the additional impedance reduces the impact of impedance variations inherent in the network of passages. FIG. 14 shows an electrical analog for unbalanced flow, using parallel resistor networks in a circuit. The analog to pressure drop is electrical voltage, and the analog to flow is electrical current. By way of example, resistors 141, 142, and 143 are assumed to be 2Ω, 3Ω, and 4Ω respectively, and V is assumed to be 12 Volts. Considering first the case where 144 are all equal to zero (short circuit), the currents in the three paths are 6 A, 4 A, and 3 A respectively: the ratio of maximum to minimum current is 2. Considering next the case where each resistor 144 is equal to 2Ω, the currents are found to be 3 A, 2.4 A, and 2 A respectively: the ratio of maximum to minimum current has been reduced to 1.5. Then considering the case where resistors 144 are each equal to 6Ω, the currents are found to be 1.5 A, 1.33 A, and 1.2 A respectively; the ratio of maximum to minimum current has been reduced to 1.25. Finally, a case is considered with three unequal resistors 144 having values 4Ω, 3Ω, and 2Ω going from left to right. In this case the resistance in each path is the same, 6Ω, and the current in each path is the same, 2 A.

From these examples, it is seen that even a modest addition of a fixed impedance to each of unequal paths can make a significant reduction to the variation in current or flow. A large fixed impedance added to each path makes a larger reduction in the variance of current or flow. Each of these solutions is suitable in situations where variations in impedance are not well characterized at the time of design, e.g. variations due to manufacturing tolerances, or when variations in impedance may be different according to process conditions. Finally, in situations where the impedance variations are well-characterized at the time of design, it is possible to exactly compensate for the impedance variations and balance flows across all paths.

A simple and effective way to add impedance is to design an orifice at the aperture between passageways of adjacent layers. Referring back to apertures 115 in FIG. 11, the apertures joining passage 112 to the lower-level passages are fairly narrow, while the aperture to passage 113 is wider, although still fairly narrow compared to the diameter of passage 113. Aperture widths can be designed to be any width up to the smaller of the two diameters of the passages being joined, and effective impedance balancing can be achieved.

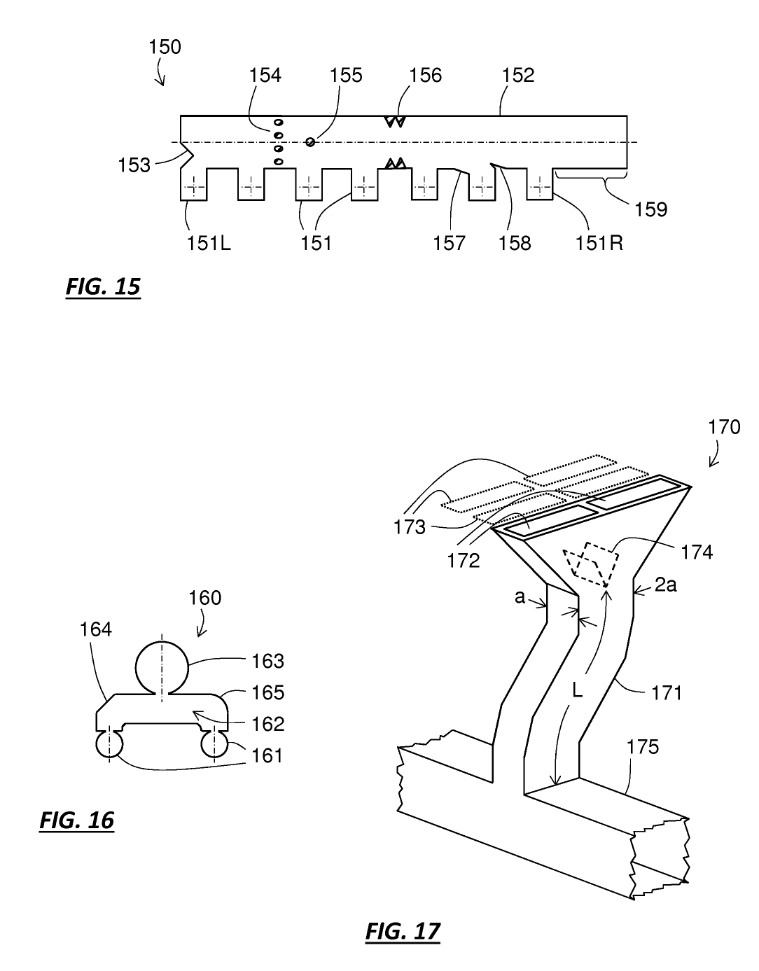

FIG. 15 shows some further mechanical elements that can be used to balance flows between different paths in one layer of a multi-manifold. 150 shows in cross-section a portion of a manifold 150 in a multi-manifold. Seven passages 151 at layer K are shown, from leftmost passage 151L to rightmost passage 151R. These passages have lengthwise extent perpendicular to the plane of the figure. 152 is a passage at layer K+1 serving all seven passages 151. A connection to layer K+2 is not shown, but could be located anywhere along the length of passage 152.

At the left end of passage 152 is a deflector 153 having a wedge shape. The principal direction of vapor flow in passage 152 is parallel to the axis of passage 152. Accordingly, vapor molecules impinging on the lower surface of deflector 153 are likely to be channeled into passage 151L. Leftward traveling vapor molecules impinging on the upper surface of deflector 153 are directed away from passage 151L. Finally, for vapor molecules impinging on the left wall of passage 152 above the upper surface of deflector 153, the upper surface casts a shadow over passage 151L and reduces the likelihood that the vapor molecules will find their way into passage 151L. Thus deflector 153 affects vapor flow from passage 152 into passage 151L. By varying the position and size of deflector 153, a suitable flow-balancing effect can be achieved.

Feature 154 is a baffle that directly introduces an impedance to flow within passage 152. Feature 155 is simply a pin that introduces an impedance to flow within passage 152 and also distorts flow lines. Pin 155 can be positioned directly above one particular passage 151 in order to increase the deflection of vapor molecules into that particular passage 151, or it can be positioned between two passages 151. Variable design features of pin 155 include its thickness, its height, and its axial position relative to the passages 151. Feature 156 is a pair of circumferential ridges along the inside wall of passage 152. Similar to baffle 154, ridges 156 serve to directly introduce impedance into the flow within passage 152. Features 157 and 158 are a chamfer and a vane respectively that serve to directly affect flow lines of vapor molecules within passage 152, and thereby increase the deflection of vapor molecules into the passage 151 between them.

Finally, extension tube 159 can also be used to reduce flow into the rightmost passage 151. In the absence of extension 159, rightward traveling vapor molecules reaching the right end of passage 152 could either be deflected downward into passage 151R, or could be reflected back to the left. In collisional flow, it is difficult for a leftward traveling molecule to make headway against a rightward traveling flow. Hence vapor molecules are preferentially deflected into passage 151R. Extension 159 serves to provide a buffer volume in which increasing numbers of vapor molecules can try to forge a leftward path, so that at passage 151R there is no longer a preponderance of rightward flowing vapor molecules, and the likelihood of deflection into passage 151R is reduced.

Any of these features can have varying features in the direction perpendicular to the plane of the figure, according to the needs of a particular design. Further, it will be apparent to one or ordinary skill in the art that these and other flow control features can be combined in any suitable combination.

Mechanical features of passageways can also be applied to streamline flow and reduce flow impedance. This may be done throughout the architecture of a multi-manifold, as it is generally desirable for a multi-manifold to have lower impedance. It may also be done at select locations, to balance impedance between different paths. Such features may include smooth bends in passageways, passageways of large cross-section, and auxiliary passageways. Interior walls may also be chemically or electropolished to make the walls smoother.

The impedance between two points may be considered to be the pressure difference between those points at a given flow. Comparing two output ports fed from the same input port, a first one may have lower flow than a second, while they discharge into the same space. Then, the path from input port to first output port would be said to have higher impedance than the path from input port to second output port. Or simply, the first output port would be said to have higher impedance. Of course, in most applications it is desirable that all output ports have the same impedance, so that all output ports of a particular manifold deliver substantially equal amounts of material to respective locations on a target surface.

FIG. 16 shows a cross-section of a portion of a multi-manifold 160, similar to that shown in FIG. 11. A passage 162 in layer K connects to two passages 161 in layer K−1 and to one passage 163 in layer K+1. In this embodiment, the distances from both passages 161 to the passage 163 are the same, and introducing features for flow balancing is not necessary. However, FIG. 16 illustrates two features, a bevel 164 and a rounded corner 165, which can be used in this and other embodiments to streamline flow and reduce flow impedance. These features may be applied either an inside surface of a bend, or an outside surface of a bend, or both.

Eqn. (3) suggests an alternative technique for balancing the flow. A modest increase in aspect ratio at layer 1 can be used to make the layer 1 contribution to overall flow impedance dominant, thus greatly reducing the effect of any imbalances introduced at higher levels, and simplifying the design process. The tradeoff lies in having considerably higher flow impedance than is otherwise necessary.

FIG. 17 shows an oblique view of a portion of exemplary manifold 170, oriented upside-down for the purpose of illustration, with output ports 172. Dotted lines represent positions of four related output ports 173 belonging to other manifolds; together these six output ports are suitable for PVD deposition of two pixels having striped layout, similar to 87 shown in FIG. 8. 171 is a substantially vertical first-level passage that serves two output ports 172, and comprises a vertical section having a lateral offset, a flare section, and an internal vane structure 174. The vertical section has a rectangular cross-section a×2a, and correspondingly a hydraulic diameter D=4a/3. The height of the vertical section is L=5a, giving an aspect ratio Z=5a/(4a/3)=3.75a, whence the term Z³ in Eqn. (3) is Z³=52.7. Thus, the impedance contribution of layer 1 largely dominates over contributions from higher layers which may have considerably larger diameter D but low aspect ratio Z≅1. First-level passage 171 is connected to and served by second-layer passage 175. In the flare section, vane 174 improves uniformity of vapor deposition through output ports 172.

Eqn. (3) also provides the motivation for the relatively complex structure of inventive multi-manifold embodiments described herein. An alternative simple structure can be imagined, where first-level passages have length equal to the extent of a target display, and are fed from one or both ends directly from a single chamber. (The end feed is necessary for this simple design in order to provide access to more than one set of interspersed output ports.) In essence, such a simple structure is similar to a multi-manifold having only two layers: a first layer in which passageways have width (and hydraulic diameter) equal to the sub-pixel stripe width, and a second layer that is a single chamber. For a typical display product or motherglass, such a first-level passage may have a length of about 1 meter, whereas the diameter of a first-level passage may be about 200 μm, giving an aspect ratio Z=(1 m/200 μm)=5,000. Accordingly the pressure drop for such a configuration is extraordinarily high. Furthermore, the flow impedance varies greatly from the single chamber to different output ports, leading to a formidable challenge trying to balance flows. Multi-layer manifolds of the style described above provide a particularly effective solution for providing low impedance balanced flow.

In a multi-manifold embodiment having a suitably flow-balanced manifold, the impedance variation from an input port to any output port is capped at +/−T % relative to the average flow impedance from the input port to any output port. Commonly the variation is limited to +/−10% (that is, T=10), preferably +/−5% (that is T=5), and often +/−2% (that is, T=2).

### Complete Layer Design

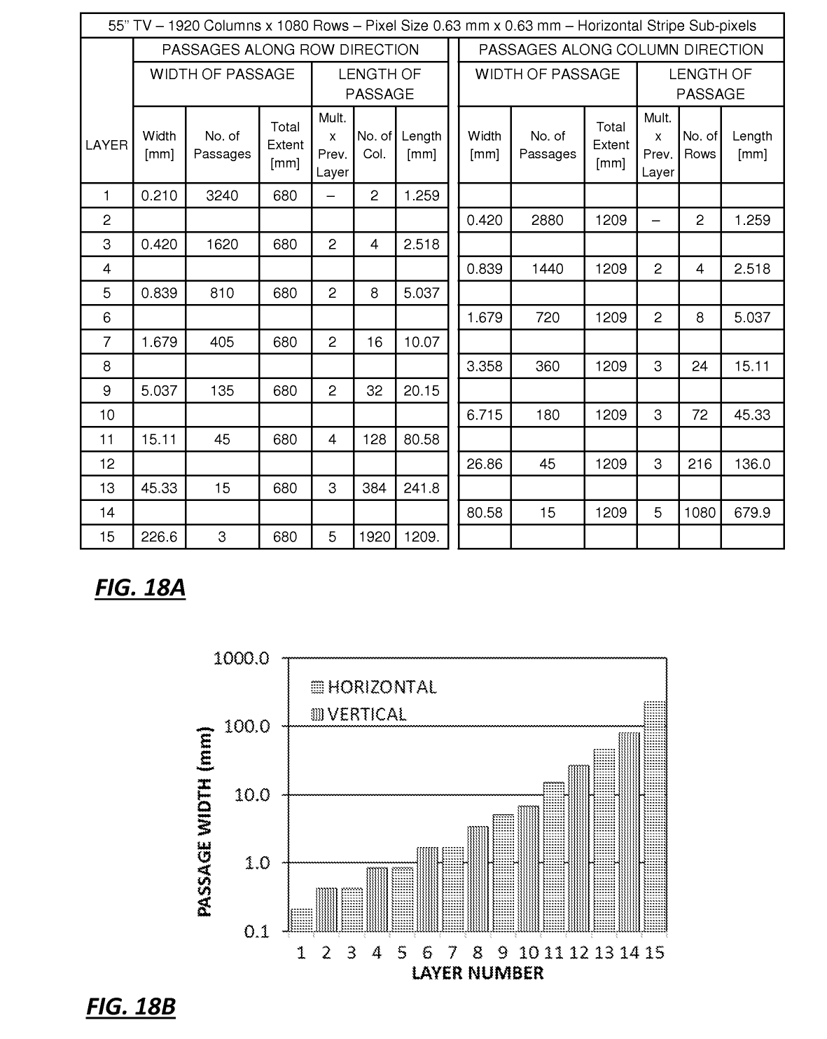

With this background, a complete manifold architecture can be considered. FIG. 18A presents a complete table for a 15-layer multi-manifold. The table development is similar to that previously presented in FIG. 9. However, in FIG. 18A, the table continues with higher layers until at layer 15 there are just 3 chambers, one for each color. Each layer 15 chamber is connected to one or more respective input ports, and the manifold is complete. The odd-numbered layers have passages in the row-wise (longer) direction. The initial length and the length-multiplying factors are chosen to be small factors of the number of columns 1920; together, the initial length and the length-multiplying factors have a product of 1920. Similarly, the even-numbered layers have passages in the column-wise direction; the initial (layer 2) passage length and the various length-multiplying factors together have a product of 1080, which is just the number of rows of the television.

In this design, two-way splits are chosen for the lowest layers as far as possible. Thereby, flow balancing is obtained without delicate fabrication of fine mechanical features at very small scale. Starting at layer 8, splits greater than two are incorporated into the design. FIG. 18B shows the progression of passage widths over the layers of the manifold, on a logarithmic scale.

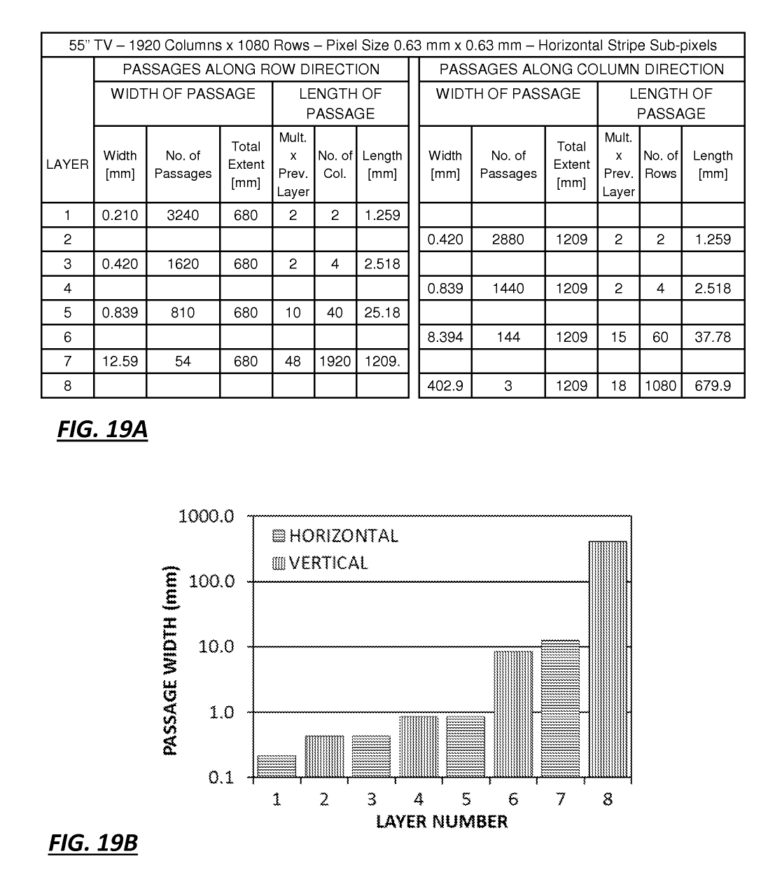

FIG. 19A shows a more aggressive design for a manifold for the same television set, using only eight layers. As before, the first two layers are fabricated using only two-way splits. For the higher layers, the expansion of passage length and passage diameter increases rapidly, by factors of 10, 15, 18, and 48. FIG. 19B shows the corresponding progression of passage widths over the layers of the manifold.

Both of these complete designs have passageway widths that are non-decreasing as the layer number increases. Generally, the passage widths increase from layer to layer, although in some embodiments a row-wise layer has passage widths that are equal to the passage widths of the preceding column-wise layer. This is a common but not necessary feature. It is easily possible, although not desirable, to design an inventive embodiment in which a manifold has progressively increasing layer widths among row-wise layers, and progressively increasing passage widths among column-wise layers, but where passage width in layer K+1 is less than the passage width of layer K.

The architecture shown for one manifold can be replicated for two other required manifolds, and a multi-manifold comprising three such entwined manifolds can be fabricated according to the concept illustrated in FIG. 6. The only difference is the precise positional offsets of the passages in each layer, which may be different from one manifold to another. For example in FIG. 6, the junctions of 62G and 61G are offset from the junctions of 62R and 61R. As explained in context of FIG. 12, positional offset does not affect the ability to design passages for balanced flow. In this way, multi-manifolds can be designed and fabricated comprising two manifolds, three manifolds, four manifolds, or even more manifolds.

It is also possible to design a multi-manifold in which not all manifolds share the same architecture, and yet the manifolds fit together in three dimensions. For a simple example, consider a multi-manifold for PVD of a four-color (RGBW) stripe display, similar to those described above. To adapt this for an RGBG stripe display, where every second stripe is green, it is possible to start with the RGBW manifold and merge the manifolds for G and W wherever passages of adjacent layers are in contact. Turning back to FIG. 6, second-layer passages 62G and 62W are each connected to all passages 61G and 61W. Accordingly, the G and W manifolds are collapsed into a single manifold having twice the number of passages as each of the B and R manifolds. Accordingly, the resulting multi-manifold has three manifolds (R, G, and B), and the G manifold has a different architecture than either the R or G manifolds. This combination of G+W manifolds into a single manifold can be done equally well whether the passages at each layer are segmented or not. For a segmented architecture, it may be noted that at each layer K, there are twice as many passages as before, spaced half as far apart. Accordingly, the passages at layer K−1 may be segmented to be half the length as before.

### Second Embodiment Class

### Multi-Manifold with Output Ports in a Block Pattern

The discussion above is primarily directed to multi-manifold embodiments in which output ports of constituent manifolds are organized as stripes. Although many features and principles of multi-manifolds are equally applicable irrespective of the patterns of output ports, there are some aspects to which particular care must be given for other output port layouts.

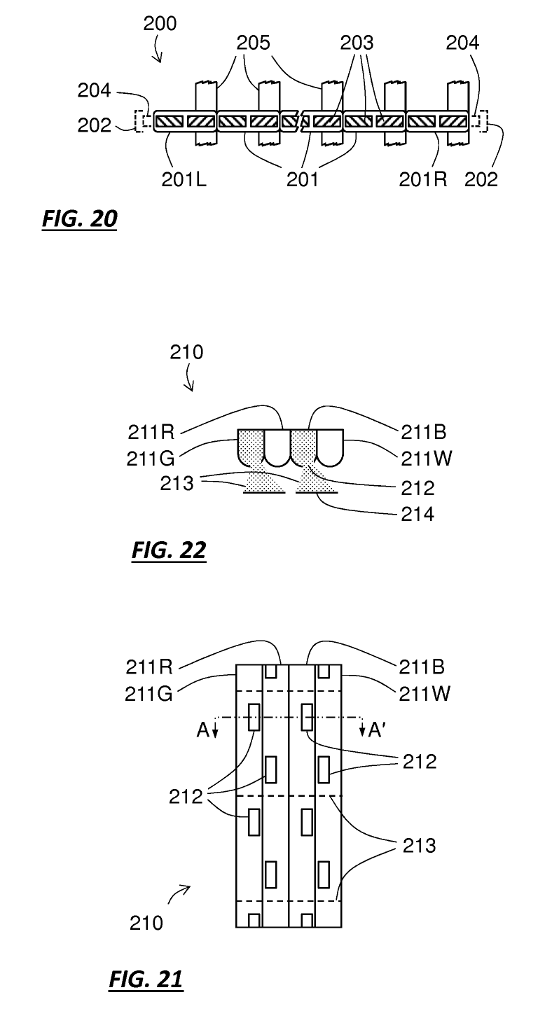

In FIG. 10, all output ports 103 shown in stripe 104 belong to the same manifold, and are fed by the same PVD source. Accordingly, it is logical that the collinear ports shown share one (un-segmented) or more (segmented) first-level passageways 101. FIG. 20 is superficially similar to FIG. 10. A design attempt for a multi-manifold 200 has a stripe 204 of output ports 203, a stripe 202 of attempted first-level passages 201, and a series of second-level passages 205. Unlike FIG. 10, output ports 203 have been shaded differently to match a block pattern, for example the left-hand column of stripe 44 shown in FIG. 4.

Thus stripe 204 comprises an alternating sequence of output ports 203, that may be considered to be green and red ports in keeping with the color conventions of FIG. 4. The pattern of output ports of a multi-manifold matches the sub-pixel pattern of an associated target display. Accordingly, for a sub-pixel similar to that shown in FIG. 4, the multi-manifold output ports form an array in rows and columns. No two neighboring output ports belong to the same manifold.

Accordingly, any particular passageway 201 can be part of a green manifold, in which case a red output port is blocked and cannot be connected to a red manifold, or this passageway can be part of a red manifold, in which case a green output port is blocked. Further, the first-level passageways cannot readily extend in a direction parallel to a second-level passage 205, since the stripe 204 is surrounded by output ports of other colors (blue and white, following FIG. 4), which also cannot be blocked. Thus, assuming the passageway dimensions are greater than equal to the output port pitch, then the layer 1 passageway must extend in a direction that is out of the plane of the figure, if adjacent output ports of other manifolds are not to be blocked. As such, there is a difficulty in connecting first-layer passageways to higher layers.

The aforementioned difficulties notwithstanding, striped first-level passageways remain a preferred design element even for multi-manifolds whose output ports are arranged in a block pattern. A few embodiments are presented below.

FIG. 21 depicts a bottom view of a portion of multi-manifold 210 having four parallel first-level passages 211G, 211R, 211B, 211W arranged in a width of one pixel having 2×2 block layout, that is, in a width of two sub-pixels. Each output port 212 is associated with one sub-pixel. The output ports are offset with respect to the centerlines of corresponding passages. FIG. 22 shows cross-sectional view AA′ from FIG. 21, during operation. Vapor is shown exiting output ports 212 and spreading in a conical pattern 213 to provide deposition coverage over sub-pixel areas 214 (not part of the instant multi-manifold) on a target substrate (not shown). As the output ports 212 are maintained at a suitable height above a target substrate, the corresponding PVD deposition profiles on the target substrate are broader than the dimensions of the output ports 212, and good coverage over target sub-pixel areas can be obtained. Since the PVD deposition profile will be broadened in both directions across the target substrate, output ports 212 have lengthwise extent smaller than the desired deposition area, as indicated in FIG. 21.

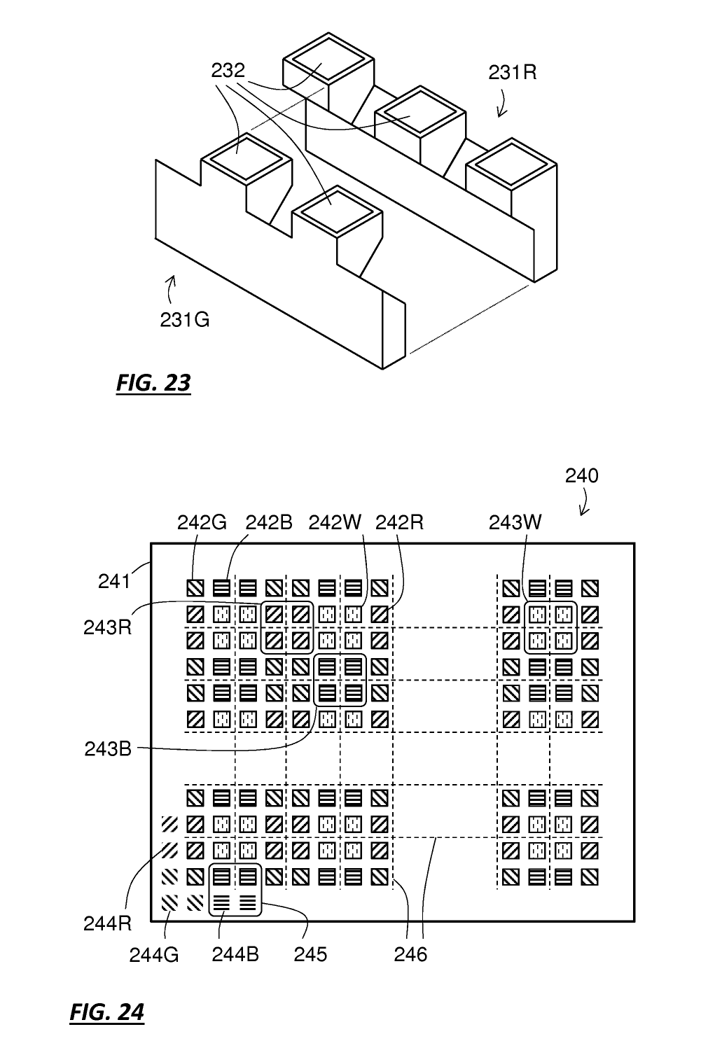

FIG. 23 depicts an alternative design of a multi-manifold embodiment, in which portions of interlocking first-level passages 231G and 231R are shown “upside-down” (that is, with output ports 232 at the top) and separated, in isometric view. In preferred embodiments, both first-level passages are manufactured together as an integral unit (often, along with many other first-level passages). For such embodiments, the depiction of first-level passages 231G, 231R as separated units is for convenience of illustration only. In this embodiment, all output ports 232 of both first-level passages 231G, 231R line up as a single stripe of output ports when the two first-level passages 231G, 231R are fitted together. The output ports 232 have a size and shape comparable to associated sub-pixels of a desired deposition pattern on a target substrate. Accordingly, the multi-manifold embodiment of FIG. 23 and the target substrate can be positioned in close proximity, or even touching, and lateral spreading of vapor-deposited materials can be controlled to be minimal. Moving away from the plane of the output ports, the first-level passageway structures taper to one half the sub-pixel width. The first-level passageways 231G, 231R are symmetric and there is no wasted space: at every height, exactly half the available area is part of passageway 231G and exactly half is part of passageway 231R.

While the embodiments described above make no mention of septa or segmenting, one of ordinary skill in the art will understand that all the same features and considerations are applicable to striped first-level passageways for block-patterned output ports as were discussed above for stripe-patterned output ports. Particularly, first-level passageways may have a length equal to the full extent of the multi-manifold, a target display, or they may be segmented to cover integer groups of output ports, including groups of two or four output ports.

An advantage of the stripe embodiments for first-level passages is that end effects are minimal, and may even be non-existent.

It should be noted that for a square pixel (such as pixel 43 shown in FIG. 4), each stripe first-level passageway described above has a width equal to one quarter the width of the pixel. This is comparable to the case for a square stripe pixel (similar to those shown as 87 in FIG. 8), where each first-level passage had a width equal to one-third the width of a pixel.

Because the stripe first-level passages are substantially similar to those previously described (in context of striped output ports and FIGS. 6, 8, and 10), the higher-level passageways and connections are also substantially similar. Similar considerations apply and similar designs can be used. Groups of first-level passages may be connected to respective orthogonal second-level passages that are fewer in number and have greater or equal cross-section as compared to the first-level passages, and so on to higher layers until at the highest layer there is a single chamber connected to one or more input ports for each manifold of the multi-manifold.

### Mirrored Pixel Layout

In order to alleviate manufacturing and process issues that may be incumbent upon very narrow first-level passageways, FIG. 24 depicts an embodiment of a display 240 in which a target substrate 241 supports an array of pixels arranged as a 2×2 block of sub-pixels. Dashed lines 246 represent pixel boundaries. Each pixel comprises one each of a red sub-pixel 242R, a green sub-pixel 242G, a blue sub-pixel 242B, and a white sub-pixel 242W. Of course, other sub-pixel colorings may be used. Unlike FIG. 4, the block patterns of pixels are arranged such that adjacent pixels have mirror-image patterns. In this embodiment, groups of four sub-pixels, such as 243R, are all the same color, and accordingly may be deposited from a single output port of a multi-manifold. Other exemplary single-color sub-pixel groups 243W and 243B are also shown. Thus, each output port can have twice the size of a display sub-pixel in each of the column-wise and row-wise dimensions, which facilitates both the manufacture of a multi-manifold and its operation in a PVD process.

It should be noted that the edge pixels (for example, above or to the right of sub-pixel group 243W) do not neatly fall within groups of four sub-pixels. To address such an end effect, several approaches are possible. Firstly, edge sub-pixels may not be subject to the same tight constraints of deposition uniformity as are interior sub-pixels, and some deviation in flow uniformity may be acceptable. Then, flow balancing may be achieved by suitable design of the passageways, by a variety of techniques including those discussed above. Alternatively, dummy sub-pixels can be incorporated around the edges of the display, so that for vapor deposition all blocks of four sub-pixels are complete. Illustrative dummy sub-pixels 244R, 244G, 244B are shown; 245 is a group of four sub-pixels that has been completed by the addition of two dummy sub-pixels 244B. The dummy sub-pixels are not electrically connected as active display elements, and the fact they are not part of any 2×2 pixel is of no consequence.

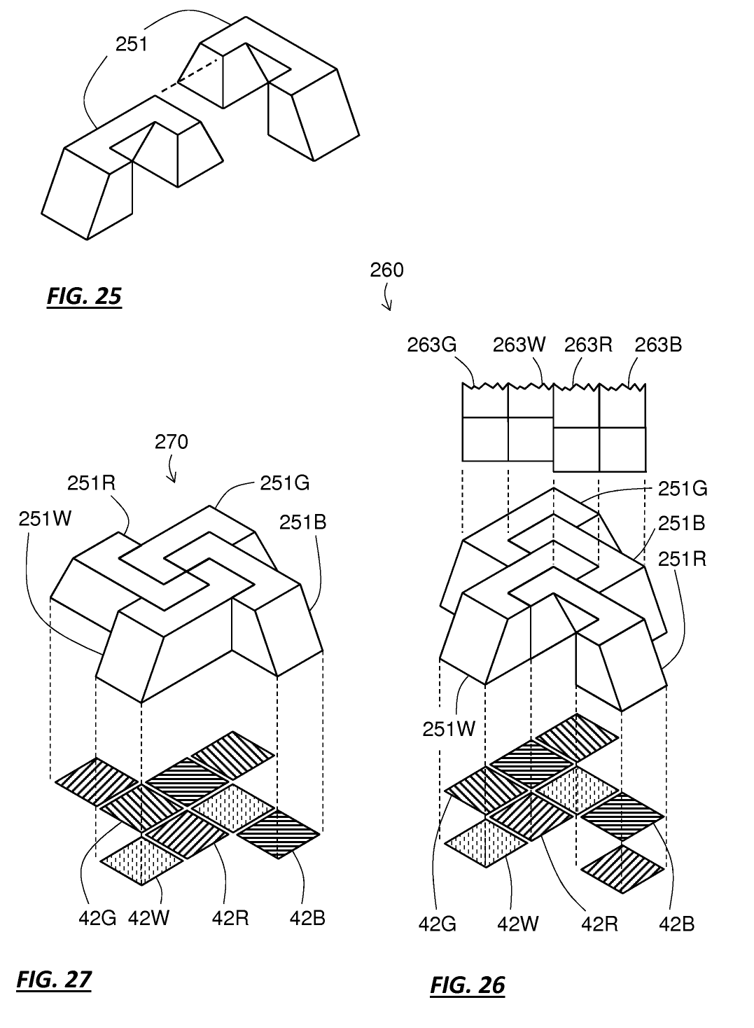

Embodiments for 2×2 block patterns of output ports are not limited to stripe first-level passageways. For example, FIG. 25 illustrates a symmetric two-way split structure suitable for layer 1 of a multi-manifold for a regular 2×2 block pattern, with two identical elements 251 shown in isometric view.

FIG. 26 shows a section of a multi-manifold 260, using elements 251. Four structures 251R, 251G, 251B, 251W are shown, each of which is a first-level two-way split passageway for a respective manifold. Below the structures is shown the sub-pixel coverage on an exemplary pixel layout of a target substrate similar to that of FIG. 4. The combination of four first-level structures 251R, 251G, 251B, 251W provides coverage of two each of red sub-pixel 42R, green sub-pixel 42G, blue sub-pixel 42B, and white sub-pixel 42W. The herringbone pattern of the first-level structures 251R, 251G, 251B, 251W can be extended and repeated to provide coverage of at least all sub-pixels on the interior of a target display pattern. Edge sub-pixels can be covered by extending the sub-pixel pattern with dummy sub-pixels as described above, or special layer 1 structures can be implemented to provide output ports for edge sub-pixels. Because there is room to extend beyond the edges of a target display, there is no particular difficulty to provide output ports for the edge sub-pixels. Layer 2 passageways can be implemented as diagonal stripes. Four such diagonal stripe passageways 263G, 263W, 263R, and 263B having square cross-section are also shown in FIG. 26. Alternatively, the first-level passageways can be connected to another layer of similar two-way split passageways at layer 2 (not shown). In addition to providing output ports, flow balance for edge pixels must also be addressed, for example by any of the approaches discussed earlier.

FIG. 27 shows a section of a multi-manifold 270, using elements 251 in a different arrangement. Four first-level structures 251R, 251G, 251B, 251W are arranged in a pinwheel configuration, providing coverage of two each of red sub-pixel 42R, green sub-pixel 42G, blue sub-pixel 42B, and white sub-pixel 42W as shown. This pattern can be repeated to provide coverage of at least all sub-pixels on the interior of a target display pattern, with handling of edge sub-pixels similar to that described above.

One of ordinary skill in the art will appreciate that first-level structures for block-patterned pixel layouts are not limited to those discussed here; other architectures of a multi-manifold are possible and within the scope of the present invention. Similarly, block-patterned output port layouts are not limited to the 2×2 block patterns or square pixels as discussed here; multi-manifolds for other block patterns and pixel shapes can be readily designed, keeping within the scope of the present invention.

### Third Embodiment Class

### Method of Manufacturing a Multi-Manifold

Multi-manifolds embodying the present invention may be manufactured from a variety of materials using a variety of manufacturing methods. Commonly, metal, polymer or plastic, and ceramic materials are used. Additive manufacturing methods are available for all of these classes of materials, and can be used advantageously to manufacture the intricate constructions of entwined and possibly interpenetrating networks of passageways.

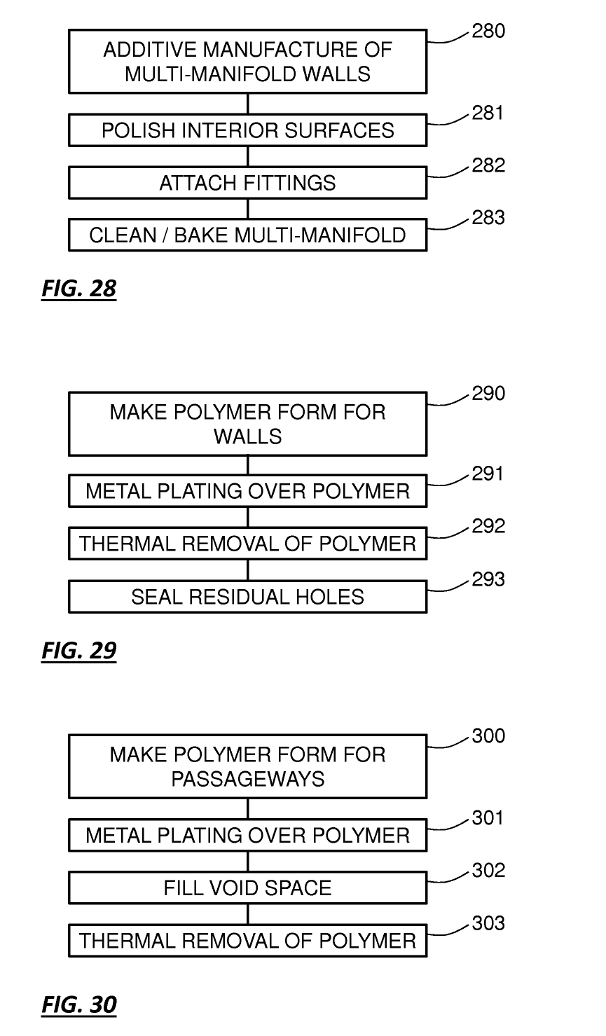

However, some additional steps may be required following additive manufacturing to render the result of the additive manufacturing process into a useful multi-manifold suitable for deployment in a process application. FIG. 28 shows such a sequence of steps. One of ordinary skill in the art will recognize that this sequence of steps is exemplary: depending on the material and the ultimate application, some steps may be unnecessary or even undesirable; it may be advantageous to perform the steps in a different order; and other similar post-processing steps may also be desirable. Further, these steps are described in context of an entire multi-manifold, but are also equally applicable to a section of a multi-manifold when the multi-manifold is manufactured in sections.

At step 280, the walls of a multi-manifold are formed by an additive manufacturing process. At step 281, the interior surfaces are polished, by a technique such as chemical polishing, electro-polishing, or a mechanical flush with an abrasive slurry and optional ultrasonication. At step 282, fittings are attached. Fittings may include input port fittings, fittings for mechanical fixturing such as hooks, bolts, standoffs, and other fixturing elements as are well-known in the art, and electrical appurtenances such as a resistive heater or a grounding strap. Fittings may often be advantageously fabricated separately from the additive manufacturing process, or even purchased, for reasons including cost, material compatibility, and special material requirements. Attachment of fittings may be performed by a variety of well-known techniques including but not limited to one or more among adhesives, mechanical fasteners, soldering, welding, brazing, and fusion bonding. At step 283, the multi-manifold is cleaned, by any one or more of a variety of techniques including but not limited to chemicals, heating, plasma, and irradiation, performed singly or in combination. Baking is well-suited for metal or ceramic multi-manifolds, and ill-suited for polymer multi-manifolds. Baking provides particularly good cleanliness for semiconductor, display, and other processes where high vacuum is involved or contamination is particularly a concern. Baking under vacuum is effective at driving off water vapor.

As regards step 280, a variety of additive machining processes are available. ASTM International (earlier known as the American Society for Testing and Materials) has published Standard F2792-12a, which organizes additive machining technologies into seven classes: binder jetting, directed energy deposition, material extrusion, material jetting, powder bed fusion, sheet lamination, and vat photopolymerization. Of these, a type of powder bed fusion process known as Direct Metal Laser Sintering (DMLS) is readily available for fabrication of parts in metals such as tungsten and stainless steel. See e.g. U.S. Pat. Nos. 4,863,538; 4,938,816; 5,658,412; 5,730,925; and 5,753,274. The powder fusion technology is also applicable to plastic and ceramic materials, and may also be used to form composite structures. DMLS works directly with metal and is well-suited for fabrication of multi-manifolds intended for high-temperature applications in clean environments. DMLS is available for fabrication of parts with wall thicknesses down to 100 um and below, which is suitable many applications, including flat panel television displays. A DMLS process can be used to manufacture all the walls of a multi-manifold, defining its plurality of entwined passages belonging to a plurality of disconnected manifolds. Thus, some multi-manifolds can be manufactured as a single piece entirely using DMLS, or an equivalent additive manufacturing process with ceramic or polymer powders. Further descriptions of additive manufacturing processes may be found, for example, in U.S. Pat. Nos. 4,247,508; 4,575,330; 5,059,266; and 5,204,055.

For some applications, a finer pitch of output ports is required. Projection microstereolithography has been demonstrated to create structures with structural elements below 5 μm in width. See for example, Sun et al., Sensors & Actuators, vol. A 121, pp. 113-120, 2005; and Zheng et al., Science, vol. 344, no. 6190, pp. 1373-1377, 2014. These attainable dimensions are suitable for multi-manifolds for the manufacture of all conventional displays, including phones, tablets, computer displays, and televisions, even some microdisplays, and for many other applications as well.

Projection microstereolithography works by building a polymer structure, which can be converted to metal by subsequent steps of metal plating and thermal removal of the polymer. Such a process is shown in FIG. 29. At step 290, a polymer form is made, from a photopolymer such as 1,6-hexanediol diacrylate (HDDA). At step 291, plating is performed over the polymer structure to form the desired metal. In preferred embodiments, step 291 is performed using electroless nickel plating. Optionally, electroplating can be performed over the nickel skin to build up the wall thickness. At step 292, the polymer is removed by thermal decomposition. Finally, at step 293, the residual holes are sealed with metal, which is desirable for vacuum cleanliness. In some embodiments, the entire void space left by the removed photopolymer is filled by metal in the molten state, using capillary action, which solidifies upon later cooling. For fine pitch passageways near the output ports, the void fraction of removed photopolymer is relatively small, and the wall structure is usually strong enough to tolerate the void space, which may be filled with an inert gas such as nitrogen, argon, or carbon dioxide. However for larger passageways, the void space dimensions can be considerably larger than the plating thickness, and deformation or even collapse of a wall could occur due to a pressure imbalance between the void space and the passageways. Therefore, when projection microstereolithography is used for larger passageways, some embodiments fill the entire void space with metal, while for other embodiments strength members are designed into void space precisely to avoid problems with pressure differential. A third approach used in other embodiments is to seal the void space on the output port side, while leaving the void space open to ambient on the input port side, thereby minimizing pressure differentials during thermal cycling. One advantage of leaving the void space empty is that the weight of the multi-manifold structure is reduced. One advantage of filling the void space with metal is that thermal conductivity of the multi-manifold structure is increased, resulting in faster temperature equilibration during a process cycle. Temperature differentials across the multi-manifold have secondary but not negligible variations on flow balancing. For this reason, it is preferable to fill the voids with metal at least for the lower levels of the multi-manifold. At higher levels of the multi-manifold, thick walls may provide adequate thermal conductivity without needing 100% filling of void spaces.

The procedure described above forms multi-manifold walls around the photopolymer. In applications where projection microstereolithography is only used for finer pitch passageways close to the output ports, it is also practical to use an inverse process. In this case, the polymer form occupies the space that will ultimately become passageways of a multi-manifold. This process is shown in FIG. 30. At steps 300 and 301, a polymer form is made, and plating is performed over the polymer structure, both as previously described. In this embodiment, the polymer fills the passageways, and so the void space is accessible prior to removal of the polymer. Accordingly, at step 302, the void space is filled with metal. Finally, at step 303, the polymer is removed by thermal decomposition.

For some applications, such as large flat panel televisions, or Gen 5.5 and up motherglass, a multi-manifold may have large extent, even greater than 1 m. In such cases it may be desirable to find a lower cost manufacturing technique to make the upper levels of the multi-manifold, closer to the input port. Because of the larger dimensions, a variety of conventional manufacturing technologies are available, including casting, metal injection molding, welding, and machining. For example prefabricated pipe or tubing sections may be machined to fit, and welded together. Sheet metal forming may also be used.

As suggested above, in some embodiments a multi-manifold may be manufactured in sections, which are subsequently connected together. Sections may be organized in the vertical direction. Such sections may include, for example, a lowest section manufactured using projection microstereolithography, a midsection manufactured using DMLS, and an upper section manufactured from metal tube using conventional techniques. Sections may also be organized in the horizontal direction, for convenience in manufacture of pieces having smaller extent than a large motherglass. For example the area of a motherglass may be covered by a 2×2 group of DMLS sub-assemblies. However, such subdivision in a horizontal direction is a matter of convenience: in U.S. 2015/0076732, Kemmer et al. have addressed the problem of additive manufacturing of large structures.

Each section of a multi-manifold may itself be considered a multi-manifold, since it has walls, entwined passageways, a smaller number of input ports (at its highest layer), and a larger number of output ports (at its lowest layer).

In U.S. 2014/0074274, Douglas et al. address the problem of joining 3-D printed structures, and describe adding features to a sub-assembly to facilitate locating and attaching sections of a final product. As regards the joining step, brazing is particularly well-suited to joining metal or ceramic parts with deep blind joints.

While the discussion above has focused on metal multi-manifolds, the fabrication of multi-manifolds of other materials is also within the scope of this class of embodiments. The additive processes described above are available for polymer and ceramic manufacture also. Likewise a variety of joining technologies is also available. Polymers and plastics may be joined by fusion bonding or ultrasonic welding. Ceramics can be joined to ceramics and other materials using ultrasonic welding, brazing, transient liquid phase bonding, sol-gel chemical bonding, microwave heating, and polymer infiltration bonding. See for example, Hanson et al., Materials World, Vol. 6, No. 9, pp. 524-36, September 1998. Some of these technologies are also suitable for plastics and metal. Finally, adhesives are available for joining most material combinations. Choice of suitable joining technology is dependent on factors including the materials to be joined, the size and surface conditions of the joining surfaces, external accessibility of the joining surfaces, and whether joining materials are compatible with the application in which the multi-manifold is to be used.

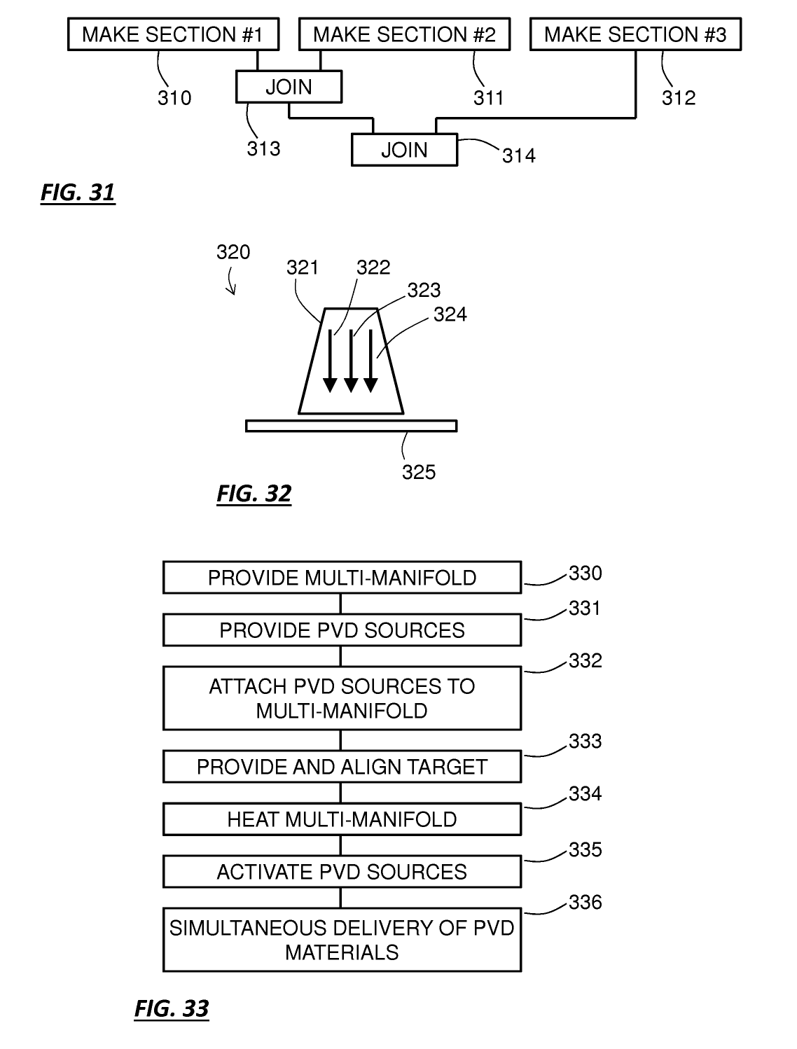

FIG. 31 illustrates the manufacturing steps for an exemplary embodiment having a multi-manifold manufactured in three sections. In steps 310, 311, and 312 the three sections are respectively manufactured. These steps may be performed concurrently, or in any order. At step 313, section 1 is joined to section 2 as discussed above. Finally the result of step 313 is joined with section 3 at step 314. Of course, the invention is not limited to three-section multi-manifolds. The number of sections comprising a multi-manifold can be any positive integer, such as one, two, three, four, or even more.

It will be understood by one of ordinary skill in the art that FIGS. 29, 30, 31, and 28 are not mutually exclusive. In an embodiment, one section of a multi-manifold may be manufactured according to FIG. 29, while another section of the same multi-manifold may be manufactured according to FIG. 30. Process steps of either FIG. 29 or FIG. 30 may be followed by process steps of FIG. 31. Process steps of any of FIGS. 29, 30, and 31 may be followed by steps of FIG. 28.

### Fourth Embodiment Class

### Method of Using a Multi-Manifold in a PVD Process

FIG. 32 depicts an exemplary embodiment of a fourth class of embodiments, in which a multi-manifold is used in a PVD process. 320 depicts part of a system in which a multi-manifold 321 delivers a plurality of vapor materials to respective sites on target substrate 325. Multi-manifold 321 is represented schematically, and comprises three operational manifolds 321, 322, and 323, each of which is used to deposit respective vapor materials onto a respective pattern of locations on the target substrate.

In the multi-manifold schematic symbol, the broad bottom edge of the trapezoid represents the plane of output ports at the lowest level of the multi-manifold, while the narrow top edge represents the input ports at the highest level of the multi-manifold. An arrow denotes each constituent manifold, pointing in the direction of fluid transport. Usually, arrows will point from the narrow input port edge to the broad output port edge.

The pattern of each manifold's output ports defines a corresponding pattern on the facing surface of target substrate 325. Since the output port patterns of manifolds 322, 323, 324 are interspersed, interspersed deposition patterns can be formed in a single process step. Interspersed patterns may be stripes, regular repeating rectangular blocks, combination patterns involving blocks with their mirror-image and/or rotated counterparts, triangular blocks, hexagonal blocks, combinations of these, or any other tiling pattern.

Preferred embodiments of the fourth class appear in the field of manufacturing flat panel displays, particularly pixelated multi-color organic light emitting diode (OLED) displays. In such embodiments, the target substrate is a display substrate, and each manifold delivers material for a patterned layer for pixels of a respective color. Commonly, the patterned layer is an emissive layer, and PVD sources provide vaporizable emissive layer materials, which are delivered through the multi-manifold as vapor, and deposited according to respective pixel patterns as an emissive layer. Other layers such as a hole transport layer may also be deposited patterned according to sub-pixel color. Sub-pixel colors may include two or more (preferably, three or more) among red, green, blue, white, and yellow.

While FIG. 32 shows three operational manifolds 321, 322, 323, it will be apparent to one of ordinary skill in the art that a similar configuration can be used with a multi-manifold comprising two, four, or more manifolds for other applications having different numbers of deposition patterns. In particular, four-color displays are becoming increasingly interesting: embodiments are known with red-green-blue-white (RGBW) pixel colors and with red-green-blue-yellow (RGBY) pixel colors, as well as other combinations. For such displays, patterned layers, including an emissive layer, can readily be manufactured using an inventive multi-manifold comprising four manifolds. Three-color displays having a four-pixel block pattern, such as red-green-blue-green (RGBG) are also known. Such displays can be manufactured using an inventive four-manifold multi-manifold, wherein two manifolds are provided with green pixel material, and one manifold each is provided with red and blue pixel material. Alternatively, an inventive three-manifold multi-manifold may be used, in which the green manifold has twice as many output ports as the red and blue manifolds, and correspondingly a different architecture.

One of ordinary skill in the art will understand that FIG. 32 has been simplified for ease of presentation. For example, the top surface of target substrate 325 facing the output ports of multi-manifold 321 is shown flat. In practice, it is often desirable for this top surface to be formed with banks separating individual deposition areas (pixels, in the case of a display). Banks serve to reduce cross-contamination of material from one manifold into the deposition areas of another manifold. Secondly, multi-manifold 321 is shown separated from target substrate 325 by a gap. In practice, and particularly when the target substrate 325 is formed with banks, it is advantageous to place the output ports of the multi-manifold 321 so that there is direct contact between (a) output ports of multi-manifold 321 and (b) the facing surface of target substrate 325, in a plurality of locations. Thereby, cross-contamination of material between deposition patterns is further reduced.

Conversely, it may be desirable to have some spread of deposited material beyond the boundaries of each output port, in particular to avoid abrupt edges in the profile of deposited material. Accordingly, in some embodiments, a gap between the target substrate and the output ports is purposefully maintained, and the gap height may be comparable to the transverse dimension of a wall thickness separating adjacent ports. In other embodiments, the gap height may be comparable to the transverse dimension of the output port. Comparable dimensions are understood to mean two dimensions that are within a factor of two, when measured in the same units.

Spreading of deposited material may also be desirable when an output port has smaller dimensions than a corresponding deposition area. However spreading should be restricted to a maximum of at most S % of deposited material from an output port reaching the deposition area of a neighboring output port of a different manifold. Preferably S is less than or equal to 10, desirably S is less than or equal to 5, commonly S is less than or equal to 2, and in some embodiments, S is less than or equal to 1. Close proximity between output ports of a multi-manifold and a facing surface of a target substrate may be defined in terms of S; for example, any distance at which the fraction of (green) deposited material reaching the deposition area of a neighboring (red) output port is less than 1%.

FIG. 33 is a flowchart illustrating use of the system 320. At step 330, multi-manifold 321 is provided. At step 331, a set of at least two PVD sources is provided. At step 332, these PVD sources are attached to respective input ports of at least two manifolds 322, 323, (324) of the multi-manifold 321. At step 333, a target substrate is provided and arranged to be in proximity to (or, in contact with) the output ports of the multi-manifold 321, and further so that the output ports of multi-manifold 321 are aligned with a desired deposition pattern on the surface of the target substrate that faces the output ports of multi-manifold 321. At step 334, the multi-manifold is heated to a temperature above the highest vaporization temperature of the vaporizable materials among the set of PVD sources. At step 335, the PVD sources are activated. Accordingly, as shown at step 336, PVD materials from the set of at least two PVD sources are delivered through output ports of respective manifolds to respective patterns on a facing surface of target substrate 325. Through the operation of the multi-manifold 321, each output port delivers PVD material to a corresponding location on the target substrate 325. Since the output ports of the several manifolds of the multi-manifold 321 are arranged in interspersed patterns, corresponding interspersed patterns of respective PVD material are deposited simultaneously onto the target substrate 325.

### Fifth Embodiment Class

### Method of Using a Multi-Manifold in a CVD Process

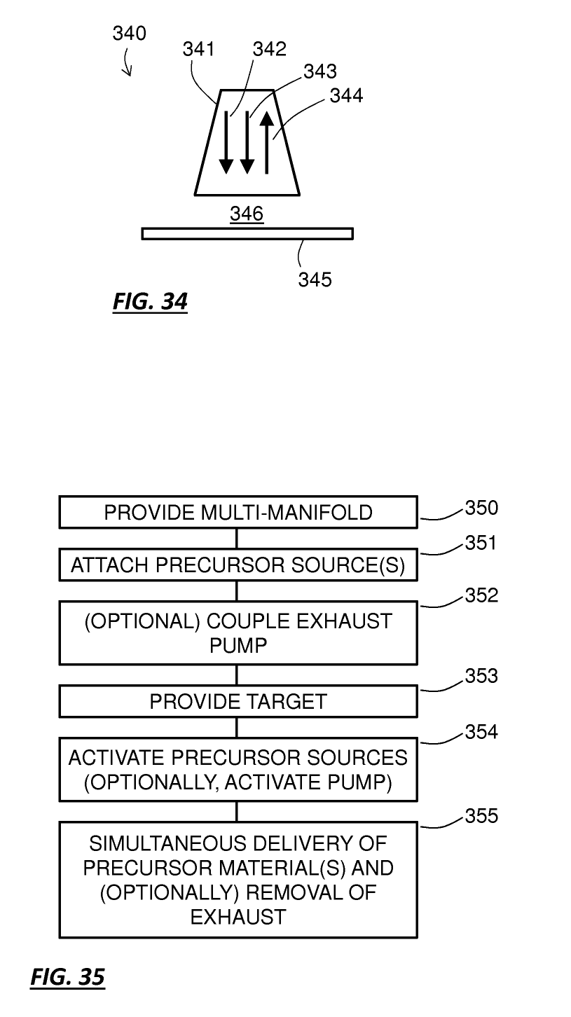

FIG. 34 depicts an exemplary embodiment of a fifth class of embodiments, in which a multi-manifold is used in a CVD process. 340 depicts part of a system in which a multi-manifold 341 delivers at least one precursor vapor to reaction zone 346 over target substrate 345. Multi-manifold 341 is represented schematically, and comprises three operational manifolds 342, 343, and 344. 342 and 343 deliver respective precursor material to the reaction zone; the direction of vapor flow being indicated by the direction of respective arrows. In the embodiment shown, manifold 344 is operated in reverse and serves to exhaust reaction by-products to a pump (not shown).

One of ordinary skill in the art will recognize that different embodiments may use different numbers of manifolds. For example, some embodiments will provide only one precursor flow through one manifold to the reaction zone. Other embodiments may provide three, or even more, precursor flows to the reaction zone. The multi-manifold may also be used to deliver one or more inert gases, such as Nitrogen or Argon, to the reaction zone. The inert gas facilitates entrainment of precursor gases, improves the consistency of mixing and reaction rate, and enables better process control. Further, a separate manifold of the multi-manifold may be used, for example, to introduce a tracer. The tracer may be delivered continuously throughout the process, or it may be applied according to a predetermined temporal profile, according to diagnostic needs of the application.

The use of the multi-manifold for an exhaust function provides for consistent and quick removal of reaction byproducts and unspent reaction material, and greatly reduces cross-contamination between one portion of the reaction zone and another. However, some embodiments may not use the multi-manifold for an exhaust function at all.

FIG. 35 is a flowchart illustrating use of the system 340. At step 350, multi-manifold 341 is provided. At step 351, precursor sources of a set of at least one precursor source are attached to respective input ports of one or more manifolds 342, (343) of the multi-manifold 341. At optional step 352, a pump is attached to the input port of manifold 344. At step 353, a target substrate is provided in proximity to the output ports of the multi-manifold 341, thereby defining a reaction region between the plane of output ports and a facing surface of the target substrate. At step 354, the precursor sources are activated, as also (optionally) the pump. Accordingly, as shown at step 355, precursor materials from the set of at least one precursor sources are delivered through output ports of respective manifolds to the reaction region 346. Optionally, reaction by-products are exhausted through a separate manifold 344 operated in reverse. Through the operation of the multi-manifold, each output port delivers precursor material(s) to a respective reaction zone (within the reaction region) associated with a corresponding location on the target substrate.

In embodiments providing CVD on a semiconductor wafer, each reaction zone may correspond to a functional block on the wafer. The functional block may be a die, a solar cell, a circuit block within a die, a sensor, or a nanomachine, according to the particular application. In other embodiments, the reaction zones may collectively serve to process a single larger area on the wafer. To avoid gaps in the reaction region between reaction zones, embodiments may provide translational motion in one or two dimensions in an amount on the order of the pitch between output ports of a single manifold, to smooth out any variations in the CVD deposition thickness.

### Sixth Embodiment Class

### Fluid Mixing Application

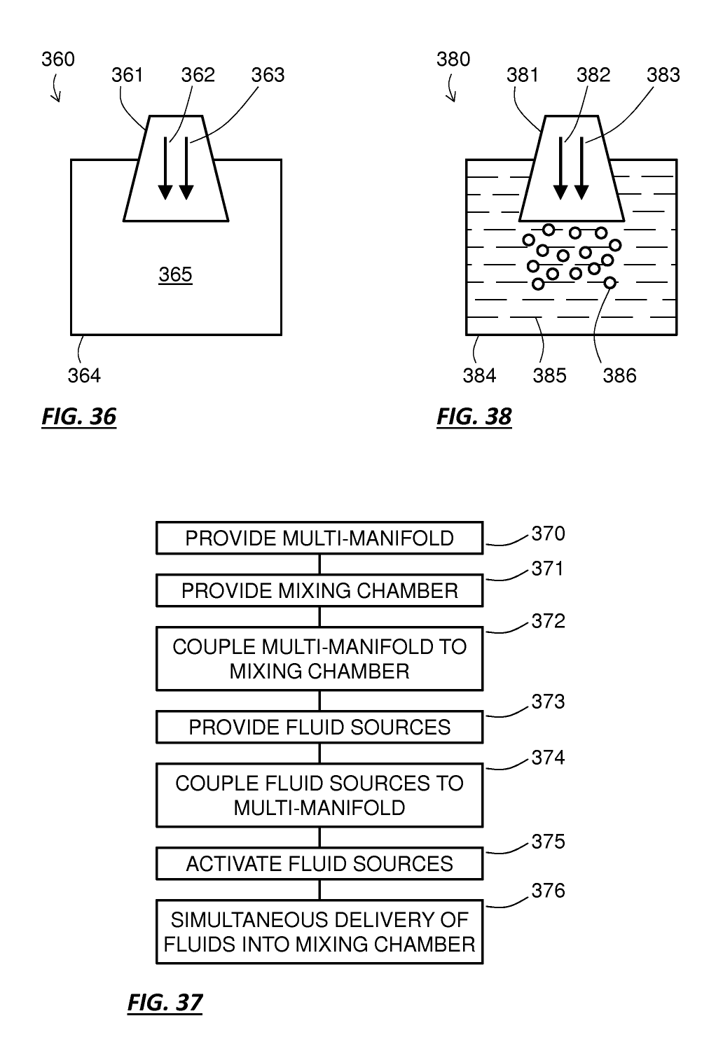

FIG. 36 depicts a sixth class of embodiments of the present invention, in which a multi-manifold is used for fluid mixing. 360 depicts part of a system in which two or more fluids are mixed. 364 is a mixing vessel, in the interior of which is mixing volume 365. Multi-manifold 361 is represented schematically, and comprises two operational manifolds 362, 363 depicted by arrows, which are operational to transfer respective fluids in the direction shown, that is, from input ports outside the mixing volume to output ports inside the mixing volume. Multi-manifold 361 may have characteristics substantially similar to one or more of the multi-manifolds previously described, or it may differ in one or more characteristics. While FIG. 36 depicts a system in which multi-manifold 361 delivers two fluids to be mixed, it will be apparent to one of ordinary skill in the art that, as the requirements of other applications require mixing of three, four, or more fluid streams, a similar configuration can be used with a multi-manifold comprising a requisite number of manifolds.

FIG. 37 is a flowchart illustrating use of the system 360. At step 370, mixing chamber 364 is provided. At step 371, multi-manifold 361 is provided. At step 372, multi-manifold 361 is arranged so that the output ports of multi-manifold 361 can discharge fluid directly into mixing volume 365. At step 373, a set of fluid sources is provided. At step 374, each of these fluid sources is coupled to a respective input port of the multi-manifold, such that at least input manifolds 362 and 363 are coupled to fluid sources. Then, at step 375, the set of fluid sources is activated. Thereby manifolds 362 and 363 simultaneously deliver respective fluids through their output ports into mixing volume 365, as indicated by step 376.

In some embodiments of this class, mixing chamber 364 is a reaction chamber, such as a combustion chamber, which may be part of an engine. In some embodiments, all fluids delivered into mixing chamber 364 are gaseous, while in other embodiments, all delivered fluids are liquids. In still other embodiments, at least one fluid is a liquid, while at least one other fluid is gaseous. Further embodiments may transport fluid as a liquid through a manifold, but have the liquid vaporize as it emerges from output ports of a multi-manifold. Other embodiments may transport fluid as a gas through a manifold, but have the gas dissolve or condense into a liquid phase as the gas emerges from output ports of a multi-manifold.

FIG. 37 depicts an embodiment of this type. 380 is part of a system in which at least one gas is to be mixed with at least one liquid. As shown, two manifolds 382 and 383 of multi-manifold 381 are operational to deliver respective fluids into mixing chamber 384. In some embodiments, a first fluid is a liquid 385, while a second fluid is a gas. For these embodiments, 386 depicts a bubble of the gas. Some such embodiments are bubble reactors, as are used in some processes for the manufacture of nano-particles. Such an arrangement employing an inventive multi-manifold provides a parallel liquid flow interspersed along with the gas bubbles, and is advantageous over a conventional system lacking the parallel interspersed liquid flow. The parallel interspersed liquid flow provides entrainment of the bubbles, and a high-inertia flow (liquids being much denser than gases) away from the plane of output ports, preventing early coalescence of emergent bubbles. The parallel interspersed gas and liquid flows provide consistent mixing properties between the two fluids, and better process control of any attendant reactions.

In other embodiments, the first fluid is a gas 385, while the second fluid is a liquid. For these embodiments, 386 in FIG. 38 depicts a liquid particle, which may be discharged into the mixing chamber in the form of a fine mist or as atomized particles. In some embodiments, at least one delivered liquid is a fuel, and at least one delivered gas is an oxidizing agent. The advantages of such an arrangement are similar to those of the bubble mixing chamber previously described. The parallel interspersed streams delivered by multi-manifold into mixing chamber 384 provide dispersal of emergent liquid particles, consistent and homogeneous concentration of liquid particles amid the gas stream, consistent mixing properties, and better process control of any attendant reactions.

Referring again to FIG. 36, the pressure of fluid streams delivered by manifolds 362 and 363 need not be the same, and can be set, controlled, and/or varied to suit the needs of any particular application. For example, with reference to FIG. 36, manifold 362 may deliver a first fluid into mixing volume 365 at a higher pressure than the pressure at which manifold 363 delivers a second fluid into the mixing volume 365.

Additionally, embodiments of the invention are well suited to the use of tracers. One or more delivered fluids may comprise a tracer. Radioactive tracers and/or dyes may be used.

### Seventh Embodiment Class

### Manufacturing Systems

A system for manufacturing a display may incorporate a multi-manifold as described above. Such a system may comprise a plurality of PVD sources, the multi-manifold, a target substrate, and a chamber housing at least part of the multi-manifold and the target substrate, and fitted with conveyances for mechanical transport of the target substrate, relative positioning of the target substrate and the multi-manifold, pumping, and process monitoring equipment. The PVD sources are connected to input ports of the multi-manifold, and the multi-manifold is positioned in close proximity to the target substrate. In some preferred embodiments, the display may be an organic electroluminescent display, sometimes referred to as an OLED display, and the PVD sources may comprise host and/or dopant materials for emissive layers of sub-pixels of different emissive colors.

A system for coating a product in a patterned PVD process may incorporate a multi-manifold as described above. Such a system may comprise some or all of the same elements described above for the display manufacturing system. One or more PVD sources are connected to input ports of the multi-manifold, and the multi-manifold is positioned in close proximity to the target substrate.

A system for coating a product in a CVD process may incorporate a multi-manifold as described above. Such a system may comprise one or more CVD sources, the multi-manifold, a target product, and a chamber housing at least part of the multi-manifold and the target substrate, and fitted with conveyances for mechanical transport of the target substrate, relative positioning of the target substrate and the multi-manifold, pumping, and process monitoring equipment. In some embodiments, a pump is provided connected directly to one or more input ports of the multi-manifold, for the purpose of providing exhaust from one or more reaction zones above the target substrate. In some embodiments, the system comprises exactly one CVD source. In other embodiments, the system comprises exactly two CVD sources. In further embodiments, the system comprises three or more CVD sources. The one or more CVD sources are connected to input ports of the multi-manifold.

A system for fluid mixing may incorporate a multi-manifold as described above. Such a system may comprise one or more fluid sources, the multi-manifold, and a discharge chamber housing at least part of the multi-manifold, and fitted with conveyances including pumping equipment for discharging mixed or spent fluid or other materials from the discharge chamber, and process monitoring equipment. The fluid sources may be sources of gas, liquid, suspensions, colloids, smoke, and mixed-phase fluids such as aerosol streams or liquids with entrained bubbles. The discharge chamber may be a chemical reactor, a bubble reactor, and/or a combustion chamber.

Furthermore, manufacturing systems are not limited to just one multi-manifold. A system may employ two or more multi-manifolds. Two or more multi-manifolds may be operated simultaneously over different portions of a target object, including on opposite sides of the target object. Two or more multi-manifolds may be operated in sequential stages of a manufacturing process. Finally, two or more multi-manifolds may be operated in parallel on adjacent production lines.

The equipment connected to the input ports of a multi-manifold may include a load lock facility for replacing material in a connected PVD source, CVD source, or fluid source.

Process monitoring equipment may include devices for monitoring pressure, temperature, position, and/or material flow.

While specific embodiments have been described in detail in the foregoing detailed description and illustrated in the accompanying drawings, it will be appreciated by those of ordinary skill in the art that various modifications and alternatives to those details could be developed in light of the overall teachings of the disclosure and the broad inventive concepts thereof. It is understood, therefore, that the scope of the present invention is not limited to the particular examples and implementations disclosed herein, but is intended to cover modifications within the spirit and scope thereof as defined by the appended claims and any and all equivalents thereof.

All U.S. patents and patent application publications referenced above are hereby incorporated by reference as if set forth in full.

We claim:

1. A method of using a multi-manifold in a physical vapor deposition (PVD) process, comprising:
a) providing a multi-manifold comprising a plurality of manifolds, each having at least one input port and a plurality of output ports;
wherein the plurality of output ports of all the manifolds collectively form a pattern;
b) providing a first source set comprising a plurality of PVD sources;
c) attaching to at least one input port of each manifold a respective PVD source from among the first source set;
wherein each PVD source comprises a respective vaporizable material having a respective vaporization temperature;
d) providing a target substrate;
e) positioning the multi-manifold in proximity to the target substrate, with the pattern of output ports positioned according to a desired deposition pattern on the target substrate;
f) heating the multi-manifold to a temperature above the highest vaporization temperature among all the vaporizable materials in the first source set;
g) activating all the PVD sources of the first source set;
whereby all manifolds operate to simultaneously deposit respective vaporizable materials through their output ports onto respective locations of the target substrate.

2. The method of claim 1, wherein the target substrate is a display substrate, and the vaporizable materials comprise emissive layer materials for respective pixel colors.

3. A system for simultaneously depositing a plurality of patterned PVD coatings, comprising:
a) a multi-manifold comprising a plurality of entwined disconnected manifolds, each manifold further comprising at least one input port and a plurality of output ports;
b) a plurality of PVD sources connected to respective input ports of the manifolds;
c) a target substrate;
d) a chamber housing the target substrate and at least part of the multi-manifold; and
e) at least one conveyance for relative positioning of the target substrate and the multi-manifold.

4. The system of claim 3, wherein the target substrate comprises a display substrate.

5. The system of claim 4, wherein the plurality of output ports of all the manifolds are arranged in a first pattern that corresponds to a second pattern of sub-pixels in a plurality of colors being formed on the display substrate.

6. The system of claim 5, wherein each output port corresponds to exactly one sub-pixel.

7. The system of claim 6, wherein a first output port is offset with respect to the center of its corresponding sub-pixel.

8. The system of claim 5, wherein a plurality of output ports of one manifold are arranged in a stripe corresponding to a stripe of sub-pixels of a same color among the plurality of colors.

9. The system of claim 5, wherein a first output port of a first manifold has neighboring output ports, none of which belong to the first manifold.

10. The system of claim 9, wherein the first output port corresponds to exactly one sub-pixel.

11. The system of claim 9, wherein the first output port corresponds to exactly four sub-pixels of a same color among the plurality of colors.

12. The system of claim 5, wherein the cross-sectional dimensions of a first output port are between 100 μm and 1 mm.

13. The system of claim 5, wherein each PVD source provides a material for an emissive element of a corresponding one of the plurality of colors.

14. The system of claim 13, wherein at least one PVD source provides an organic emissive layer material.

15. The system of claim 13, wherein the at least one PVD source provides a material comprising a host material and a dopant material.

16. The system of claim 1, wherein at least one PVD source comprises a load lock mechanism.

17. The system of claim 1, wherein the multi-manifold comprises exactly three manifolds.

18. The system of claim 1, wherein the multi-manifold comprises exactly four manifolds.
